(19) United States
(12) Patent Application Publication
(10) Pub. No.: US 2026/0304821 A1
(43) Pub. Date: Oct. 1, 2026

(54) BILAYER STRUCTURES FOR TRANSISTOR CHANNEL LAYERS

(71) Applicant: Monash University, Clayton (AU)

(72) Inventors: Yuefeng YIN, Melbourne (AU); Nikhil V. MEDHEKAR, Melbourne (AU); Michael Sears FUHRER, Ormond (AU)

(73) Assignee: Monash University, Clayton (AU)

(21) Appl. No.: 19/573,979

(22) Filed: Mar. 20, 2026

Related U.S. Application Data
(60) Provisional application No. 63/779,586, filed on Mar. 28, 2025.
(60) Provisional application No. 63/848,509, filed on Jul. 22, 2025.
(60) Provisional application No. 63/932,149, filed on Dec. 5, 2025.

(51) Int. Cl. H10D 30/47; H10D 30/01; H10D 30/69; H10D 62/80

(52) U.S. Cl. CPC H10D 30/481; H10D 30/017; H10D 30/0415; H10D 30/701; H10D 62/883

(57) ABSTRACT

A negative capacitance bandgap-change field-effect transistor (NC-BCFET) includes a channel with a bilayer heterostructure comprising two semiconductor material layers and an insulating layer between them. The semiconductor material layers are each 1 monolayer or from 1-20 Å thick. The transistor also includes a source, drain, and two gate layers, where each gate layer is in contact with a ferroelectric layer, and the ferroelectric layers are in contact with the channel. The source and drain are spaced apart from one another, and the ferroelectric layers are in contact with the channel in a region located between the source and the drain. In some cases, the semiconductor material can be selected from P, As, Sb, Bi, Si, Ge, Sn, Pb, WS₂, WSe₂, MoSe₂ and MoS₂.

### RELATED APPLICATIONS

This application claims the benefit of U.S. Provisional Patent Application No. 63/779,586, filed on Mar. 28, 2025, and entitled “Bilayer Structures for Transistor Channel Layers”; and U.S. Provisional Patent Application No. 63/848,509, filed on Jul. 22, 2025, and entitled “Bilayer Structures for Transistor Channel Layers”; and U.S. Provisional Patent Application No. 63/932,149, filed on Dec. 5, 2025, and entitled “Bilayer Structures for Transistor Channel Layers”; the contents of which are incorporated herein by reference in their entirety.

### BACKGROUND

An electric field can be used to manipulate the electrical properties of two-dimensional thin films. For example, an electric field effect has been used to modify the bandgap of a structure including bilayer graphene. In another example, an electric field has been used to switch the bandgap in topologically nontrivial thin films. Models and field-effect transistor (FET) architectures for these structures have also been used to describe that topological materials with certain atomic structures and strong spin-orbit coupling may have a strong dependence of the bandgap on electric field. Additionally, a structure incorporating ferroelectric layers and a topological insulator channel layer has been described to amplify the electric field within the topological insulator, achieving switching at a lower voltage. A theoretical model using an electric field to control the edge transport in topologically nontrivial thin films has also been proposed.

FIG. 1 is an illustrative cross-sectional view of a negative capacitance topological quantum field-effect transistor (NC-TQFET) structure in which the applied voltage switching requirement is reduced by utilizing ferroelectric layers instead of a gate insulator layer used in traditional metal-oxide-semiconductor field-effect transistors (MOSFETs). The reduced voltage switching requirement can reduce energy consumption. The NC-TQFET structure includes a channel with a channel material electrically coupled to source and drain electrodes. The channel is located between two gates (“Gate 1” and “Gate 2”) of the device. A first layer of ferroelectric material separates “Gate 1” from the channel, and a second layer of ferroelectric material separates “Gate 2” from the channel. The first and second ferroelectric material layers act as a negative capacitor. The NC-TQFET structure has been described for use as a field-effect transistor with a low switching voltage in cases where (1) the channel material is a semiconductor whose bandgap depends on the electric field, and (2) the absolute magnitude of the negative capacitance of the ferroelectric layers is chosen to be close to, and slightly larger than, the positive capacitance of the channel layer such that the total capacitance of the ferroelectric/channel/ferroelectric stack is positive. In such cases, the electric field in the channel is amplified relative to the applied electric field, only if the voltage between “Gate 1” and “Gate 2” is dropped across the channel.

### SUMMARY

In some aspects, the techniques described herein relate to a negative capacitance bandgap-change field-effect transistor (NC-BCFET) including: a channel including a bilayer heterostructure including: a first layer of a semiconductor material; a second layer of the semiconductor material; and an insulating layer between the first and second layers of the semiconductor material; wherein the first and second layers of the semiconductor material each include a thickness of 1 monolayer, or from 1 Å to 20 Å; a source in contact with a first region of the channel; a drain in contact with a second region the channel; a first ferroelectric layer in contact with a first side of the channel; a first gate layer in contact with the first ferroelectric layer, wherein the first ferroelectric layer is between the first gate layer and the channel; a second ferroelectric layer in contact with a second side of the channel opposite the first side; and a second gate layer in contact with the second ferroelectric layer, wherein the second ferroelectric layer is between the second gate layer and the channel; wherein the first and second regions are spaced apart from one another, and the first and second ferroelectric layers are in contact with the channel in a third region located between the first and second regions.

In some aspects, the techniques described herein relate to a negative capacitance bandgap-change field-effect transistor (NC-BCFET) including: a channel including: a first layer of a semiconductor material; a second layer of the semiconductor material; and an insulating layer between the first and second layers of the semiconductor material; wherein the semiconductor material is selected from P, As, Sb, Bi, Si, Ge, Sn, Pb, WS₂, WSe₂, MoS₂ and MoSe₂.

### BRIEF DESCRIPTION OF THE DRAWINGS

Aspects of the present disclosure are best understood from the following detailed description when read with the accompanying figures. It is emphasized that various features are not drawn to scale in accordance with the standard practice. In fact, the dimensions of the different features may be arbitrarily increased or reduced for clarity of discussion. In addition, the present disclosure may repeat reference numerals and/or letters in the various examples. This repetition is for simplicity and clarity and does not in itself dictate a relationship between the various examples and/or configurations discussed.

FIG. 1 is an illustrative cross-sectional view of a known negative capacitance field-effect transistor (NC-TQFET) structure.

FIG. 2A is an illustrative cross-section view of an example of a heterostructure material in accordance with some examples.

FIG. 2B is an illustrative cross-section view of an example NC-BCFET incorporating a channel that includes the heterostructure material of FIG. 2A.

FIG. 2C is a conceptual drawing representing the response of conduction (electron) and valence (hole) energy bands of the heterostructure material of FIG. 2A to changes in a gate electric field of the NC-BCFET of FIG. 2B. In the OFF-state, at zero applied electric field, the conduction bands (c1,c2) are degenerate or nearly degenerate, and the valence bands (v1,v2) are degenerate or nearly degenerate. The conduction bands (c1,c2) and valence bands (v1,v2) are separated by an energy bandgap Eg. In the ON-state, upon the application of an electric field, the conduction bands are split into bands c1 and c2, and the valence bands into bands v1 and v2, which move in opposite directions in energy, reducing the bandgap.

FIG. 2D is an illustrative cross-section view of an example channel structure having an example thickness t_{channel}.

FIGS. 2E-2J show schematic cross-sections of structures that can be used in NC-BCFET devices.

FIG. 2K shows illustrative graphs of electric potential versus perpendicular distance during OFF-state and ON-state operation of an example NC-BCFET of FIG. 2B.

FIG. 2L is a conceptual drawing showing relationships between conduction (electron) energy bands (c1, c2) and valence (hole) energy bands (v1, v2) of a symmetric channel as a function of momentum, when the device is in an OFF-state (shown on left) and when the device is in an in an ON-state (shown on the right).

FIG. 2M is a conceptual drawing showing relationships between conduction (electron) energy bands (c1, c2) and valence (hole) energy bands (v1, v2) of an asymmetric channel, when the device is in an OFF-state (shown on left) and when the device is in an ON-state (shown on the right).

FIG. 3A represents an illustrative monolayer (1L).

FIG. 3B represents an illustrative conventional bilayer stacking (2L-CONV).

FIG. 3C represents an illustrative reversed bilayer stacking (2L-REV).

FIG. 3D represents an illustrative bilayer stacking with tunneling (2L+TUNNEL).

FIG. 4 is an illustrative drawing representing a workflow based on DFT calculations to identify electric field-sensitive heterostructure materials.

FIG. 5A is an illustrative drawing that represents bilayer monoelemental layers.

FIG. 5B is an illustrative drawing that represents bilayer monoelemental layers with a tunneling layer.

FIG. 5C is an illustrative drawing that represents bilayer black phosphorus (orthorhombic symmetry) with a tunneling layer.

FIG. 6A is an illustrative drawing showing a DFT result indicating electronic band structure for electric field strength 0 eV/Å for bilayer stacks with respect to applied electric field for bilayer arsenene (As) separated by 8.5 Å.

FIG. 6B is an illustrative drawing showing DFT results indicating electronic band structure for electric field strength 0.05 eV/Å for bilayer stacks with respect to applied electric field for bilayer arsenene (As) separated by 8.5 Å.

FIG. 6C is an illustrative drawing showing DFT results indicating electronic band structure for electric field strength 0.40 eV/Å for bilayer stacks with respect to applied electric field for bilayer arsenene (As) separated by 8.5 Å.

FIG. 6D is an illustrative drawing showing DFT results indicating electronic band structure for electric field strength 0 eV/Å for bilayer plumbene (Pb) separated by 8.5 Å.

FIG. 6E is an illustrative drawing showing DFT results indicating electronic band structure for electric field strength 0.05 eV/Å for bilayer plumbene (Pb) separated by 8.5 Å.

FIG. 6F is an illustrative drawing showing DFT results indicating electronic band structure for electric field strength 0.2 eV/Å for bilayer plumbene (Pb) separated by 8.5 Å.

FIG. 7A is an illustrative graph representing evolution of bandgap (eV) with electric field strength (eV/Angstrom) for As, Sb, Bi, Si, Ge, Sn, Pb with conventional stacking and bilayers initially separated by 3.5 Å and for bilayer graphene.

FIG. 7B is an illustrative graph representing evolution of bandgap (eV) with electric field strength (eV/Angstrom) for As, Sb, Bi, Si, Ge, Sn, Pb with conventional stacking and bilayers initially separated by 8.5 Å and for bilayer graphene.

FIG. 7C is an illustrative graph representing evolution of t_{eff}/t_{channel} versus band gap (eV) with conventional stacking for As, Sb, Bi, Si, Ge, Sn, Pb with conventional stacking and bilayers initially separated by 3.5 Å and for bilayer graphene.

FIG. 7D is an illustrative graph representing evolution of t_eff/t_channel versus band gap (eV) with conventional stacking for As, Sb, Bi, Si, Ge, Sn, Pb with conventional stacking and bilayers initially separated by 8.5 Å and for bilayer graphene.

FIG. 8 is an illustrative graph showing evolution of band gaps (eV) versus electric field strength (eV/Angstrom) for bilayer arsenene (As) for different stacking distances.

FIG. 9A is an illustrative drawing that shows bilayer plumbene (Pb) spaced apart by a hexagonal boron nitride (h-BN) layer.

FIG. 9B is an illustrative chart that indicates lattice information for the structure of FIG. 9A.

FIG. 10A is an illustrative drawing showing DFT results indicating electronic band structure for electric field strength 0 eV/Å for the bilayer plumbene (Pb) with a h-BN layer in between of FIG. 9A.

FIG. 10B is an illustrative drawing showing DFT results indicating electronic band structure for electric field strength 0.05 eV/Å for the bilayer plumbene (Pb) with a h-BN layer in between of FIG. 9A.

FIG. 10C is an illustrative drawing showing DFT results indicating electronic band structure for electric field strength 0.2 eV/Å for the bilayer plumbene (Pb) with a h-BN layer in between, as shown in FIG. 9A.

FIG. 11A is an illustrative drawing representing relaxed geometry conventional stacked bilayer plumbene (Pb) stabilized by an h-BN tunneling layer.

FIG. 11B is an illustrative drawing representing relaxed geometry reversed stacked bilayer plumbene (Pb) stabilized by an h-BN tunneling layer.

FIG. 12A is an illustrative graph showing evolution of band gap (eV) versus electric field strength (eV/Angstrom) for relaxed geometry conventional stacked, and relaxed geometry reversed stacked bilayer plumbene (Pb) stabilized by an h-BN tunneling layer, and bilayer graphene.

FIG. 12B is an illustrative graph showing t_{eff}/t_{channel} versus band gap (eV) for relaxed geometries of conventional stacked and reversed stacked bilayer plumbene (Pb) stabilized by an h-BN tunneling layer, along with bilayer graphene.

FIG. 13 is an illustrative schematic of different numbers of h-BN layers between atomically thin semiconductor layers and studying the effects of each.

FIG. 14A is an illustrative graph showing the evolution of band gap (eV) versus electric field strength (eV/Angstroms) for 1, 2, 3, 4, 5, and 11 h-BN tunneling layers for an Pb-hBN-Pb system and for bilayer graphene.

FIG. 14B is an illustrative graph showing the evolution of t_{eff}/t_{channel} versus band gap (eV) for 1, 2, 3, 4, 5, and 11 h-BN tunneling layers for an Pb-hBN-Pb system and for bilayer graphene.

FIG. 15A is an illustrative drawing representing the geometry of bilayer black phosphorus.

FIG. 15B is an illustrative drawing representing the geometry of bilayer black phosphorus (BP) with an h-BN interlayer spacing apart the BP layers.

FIG. 16A is an illustrative graph showing the evolution of band gap (eV) versus electric field strength (eV/Angstroms) for bilayer BP, bilayer BP with h-BN in between, and bilayer graphene.

FIG. 16B is an illustrative graph showing the evolution of t_{eff}/t_{channel} versus band gap (eV) for bilayer BP, bilayer BP with h-BN in between, and bilayer graphene.

FIG. 17A is an illustrative drawing that represents bilayer WSe₂ with a tunneling or insulating layer (h-BN).

FIG. 17B is an illustrative drawing that represents bilayer MoS₂ with a tunneling or insulating layer (Al₂O₃, i.e., Sapphire).

FIG. 18A is an illustrative graph showing evolution of band gap (eV) versus electric field strength (eV/Angstrom) for relaxed geometry of bilayer WSe₂ stabilized by an h-BN tunneling layer, relaxed geometry of conventional stacked bilayer WSe₂ and bilayer graphene for comparison.

FIG. 18B is an illustrative graph showing t_{eff}/t_{channel} versus band gap (eV) with relaxed geometry of bilayer WSe₂ stabilized by an h-BN tunneling layer, relaxed geometry of conventional stacked bilayer WSe₂, and bilayer graphene.

FIG. 19A is an illustrative graph showing evolution of band gap (eV) versus electric field strength (eV/Angstrom) for relaxed geometry of bilayer MoS₂ stabilized by a sapphire tunneling layer, relaxed geometry of conventional stacked bilayer MoS₂ and bilayer graphene.

FIG. 19B is an illustrative graph showing t_{eff}/t_{channel} versus band gap (eV) with for relaxed geometry of bilayer MoS₂ stabilized by a sapphire tunneling layer, relaxed geometry of conventional stacked bilayer MoS₂, and bilayer graphene.

FIG. 20A is an illustrative drawing that represents bilayer MoS₂ with a tunneling layer that is non-polar hafnia (HfO₂).

FIG. 20B is an illustrative drawing that represents bilayer MoS₂ with a tunneling layer that is polar hafnia.

FIG. 20C is an illustrative drawing that represents bilayer MoS₂ with a tunneling layer that is low-symmetry hafnia.

FIG. 21A is an illustrative graph showing evolution of band gap (eV) versus electric field strength (eV/Å) for a relaxed geometry of bilayer MoS₂ stabilized by a non-polar hafnia tunneling layer, a relaxed geometry of bilayer MoS₂ stabilized by a polar hafnia tunneling layer, and a relaxed geometry of bilayer MoS₂ stabilized by a low-symmetry hafnia tunneling layer, compared to conventional stacked MoS₂ and bilayer graphene.

FIG. 21B is an illustrative graph showing t_{eff}/t_{channel} versus band gap (eV) for the relaxed geometry bilayer MoS₂ stabilized by a non-polar hafnia tunneling layer, the relaxed geometry of bilayer MoS₂ stabilized by a polar hafnia tunneling layer, and the relaxed geometry of bilayer MoS₂ stabilized by a low-symmetry hafnia tunneling layer, compared to the conventional stacked MoS₂ and bilayer graphene.

FIG. 22A is an illustrative graph showing evolution of band gap (eV) versus electric field strength (eV/Å) for a relaxed geometry of bilayer MoS₂ stabilized by a polar hafnia tunneling layer with electric field direction pointing from top to bottom and from bottom to top, compared to that of bilayer graphene.

FIG. 22B is an illustrative graph showing t_{eff}/t_{channel} versus band gap (eV) for the relaxed geometry of bilayer MoS₂ stabilized by a polar hafnia tunneling layer with electric field direction pointing from top to bottom and from bottom to top, compared to that of bilayer graphene.

FIG. 23A is an illustrative graph showing evolution of band gap (eV) versus electric field strength (eV/Å) for a relaxed geometry of bilayer MoS₂ stabilized by a low-symmetry hafnia tunneling layer with electric field direction pointing from top to bottom and from bottom to top, compared to that of bilayer graphene.

FIG. 23B is an illustrative graph showing t_{eff}/t_{channel} versus band gap (eV) for the relaxed geometry of bilayer MoS₂ stabilized by a low-symmetry hafnia tunneling layer with electric field direction pointing from top to bottom and from bottom to top, compared to that of bilayer graphene.

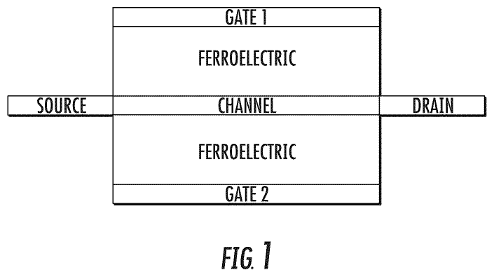

### DETAILED DESCRIPTION

The current disclosure describes new thin-film heterostructure materials that when used in a transistor, require substantially lower switch voltages than previous materials, such as bilayer graphene. For example, it is contemplated that an example negative capacitance bandgap-change field-effect transistor (NC-BCFET) structure that uses the new thin-film heterostructure material as a channel, can operate with significantly lower power consumption than traditional transistor structures.

The example NC-BCFETs described herein are distinct from a conventional negative capacitance field-effect transistor NC-FET in that the NC-BCFET has (1) two gate voltages applied to two gates (2) configured to apply an electric field across the channel and (3) configured such that the negative capacitance amplifies the electric field in the channel (4) in order to change the bandgap of the channel material. A conventional NC-FET uses a single gate voltage applied to one or more gates, with the negative capacitance designed to amplify the voltage at the channel but not designed to apply an electric field across the channel or modulate the bandgap of the channel.

The example NC-BCFETs described herein have a similar principle of operation to the previously described negative capacitance topological quantum field-effect transistor (NC-TQFET) in that both the NC-BCFET and the NC-TQFET have (1) two gate voltages (although one can be held at ground) applied to two gates (2) configured to apply an electric field across the channel and (3) configured such that the negative capacitance amplifies the electric field in the channel (4) in order to change the bandgap of the channel material. However, the NC-BCFET accomplishes the similar operation through the use of a bilayer heterostructure channel constructed from non-topological materials and does not require a topological phase transition in the channel material upon application of an electric field.

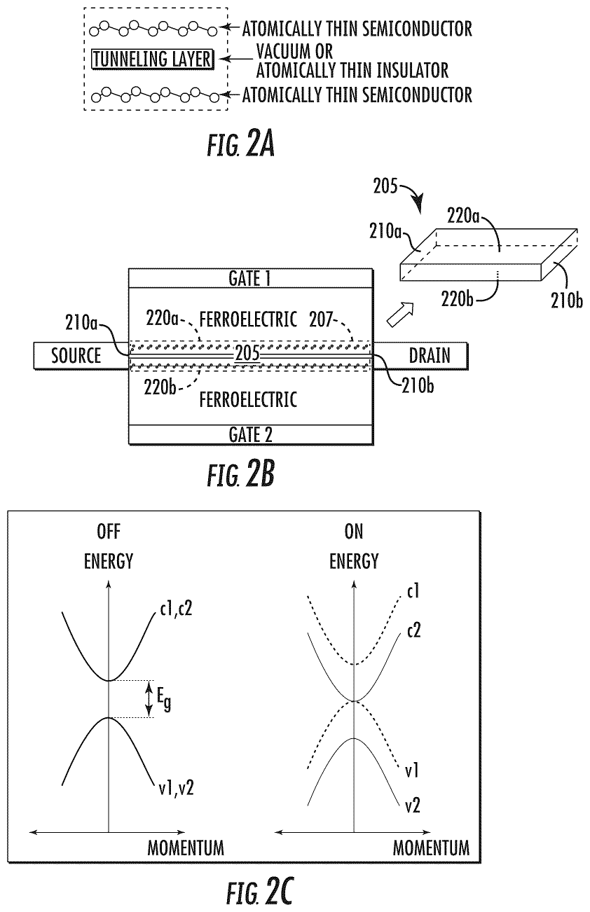

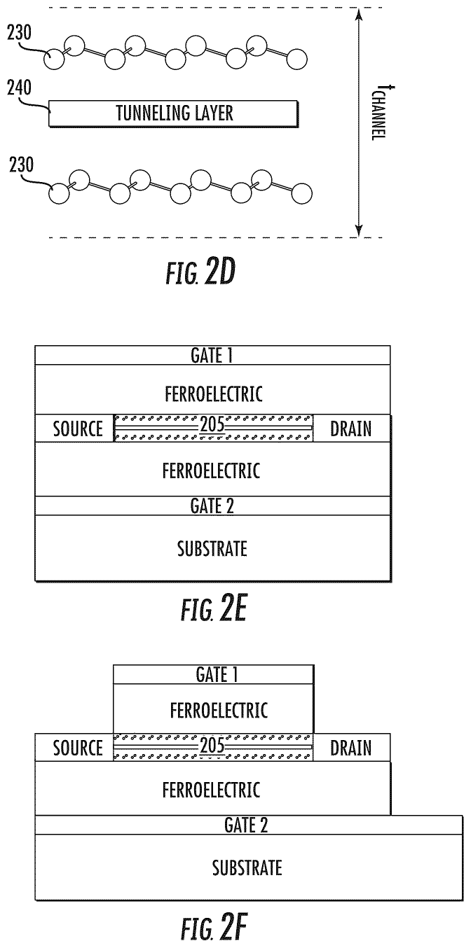

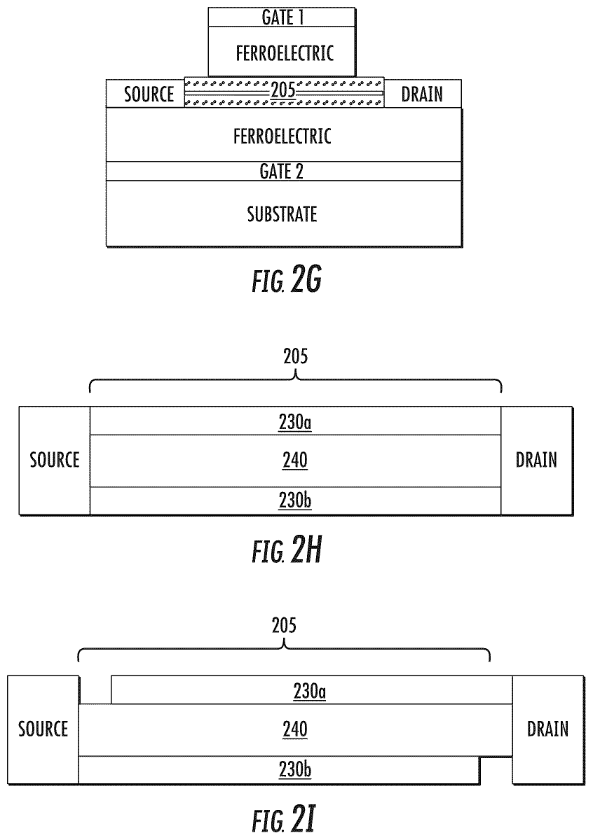

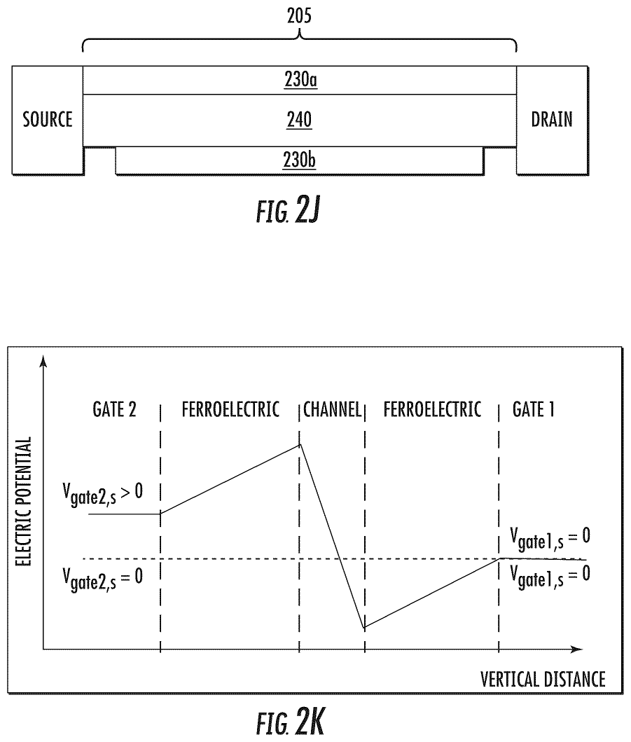

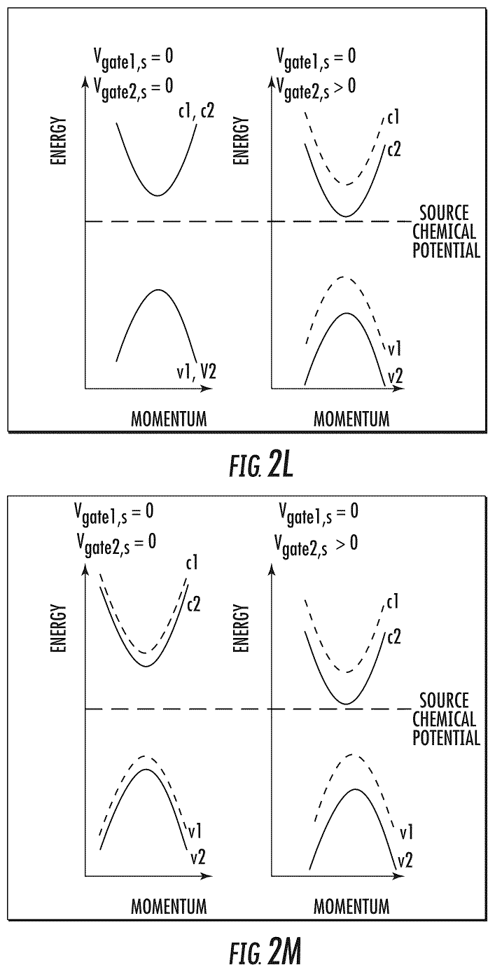

FIG. 2A is an illustrative cross-section view of an example of a heterostructure material in accordance with some examples. The heterostructure material includes two atomically thin (e.g., less than 20 Å) semiconductor layers sandwiching an electron tunneling layer comprising an insulator or vacuum layer (e.g., an atomically thin insulator or vacuum layer). FIG. 2B is an illustrative cross-section view of an example NC-BCFET incorporating a channel that includes the heterostructure material (dashed box) of FIG. 2A. FIG. 2C is a conceptual drawing representing the response of conduction (electron) and valence (hole) energy bands of the heterostructure material of FIG. 2A to changes in a gate electric field of the NC-BCFET of FIG. 2B. When the gates are not configured to apply an electric field (for example, the voltages on the top and bottom gates are equal), e.g., in the OFF-state, the conduction (c1,c2) and valence (v1,v2) energy bands of the two atomically thin semiconductor layers are nearly degenerate (i.e., c1 and c2, and v1 and v2 have nearly the same energy) and form a semiconducting band gap Eg between them. They are not completely degenerate due to the presence of tunneling through the insulator or vacuum layer, which causes the bands to hybridize, forming bands with bonding and anti-bonding character. In response to the gate electric field switching to the ON-state, the conduction and valence energy bands of the atomically thin semiconductor layers split or separate (shown as the dashed and solid bands), to effectively reduce or potentially close, the electronic band gap. In the limit of strong electric field and weak electron tunneling, the dashed and solid bands correspond to the top and bottom semiconducting layers, respectively.

FIG. 2B illustrates an example of a negative capacitance field-effect transistor (NC-BCFET) that includes a channel 205. In some cases, the channel includes a first layer of a semiconductor material and a second layer of the semiconductor material, with an insulating layer positioned between the first and second layers of the semiconductor material, for example, as shown in the bilayer heterostructure material shown in FIG. 2A. For example, the semiconductor material can be selected from P, As, Sb, Bi, Si, Ge, Sn, Pb, InSe, GaSe, (Mo,W)(S,Se)₂, WS₂, WSe₂, MoS₂, and MoSe₂, or other metals, sulfides, selenides, or transition metal dichalcogenides (TMDs). The insulating layer can be selected from a vacuum layer, BN (e.g., hexagonal-BN (h-BN)), sapphire (Al₂O₃), hafnia (HfO₂), or other nitride or oxide materials. Any of these semiconductor materials can be combined with any of these insulating materials to form the bilayer heterostructures described herein (e.g., as shown in FIG. 2A). A bias (potential or voltage) can be applied across “Gate 1” to “Gate 2,” which can cause an electric field to be formed across the channel 205, if some of the potential is dropped across the channel. A change in the bias applied across “Gate 1” and “Gate 2” can cause a change in the electric field across the channel 205 in the direction perpendicular to the channel (e.g., perpendicular to a primary direction of current flow from the source to the drain in the channel), which can cause a change in the band gap of the channel, as described herein.

The NC-BCFET in FIG. 2B can further include a source (“Source” in the figure) in contact or electrical contact with a first region 210a of the channel 205 and a drain (“Drain” in the figure) in contact or electrical contact with a second region 210b of the channel 205. In the example shown in FIG. 2B, the first region 210a of the channel is at the interface between the channel 205 and the source. In the example shown in FIG. 2B, the second region 210b of the channel 205 is at the interface between the channel and the drain.

The NC-BCFET may also include two gate layers (“Gate 1” and “Gate 2”) that are coupled to (e.g., capacitively coupled to) a third region 207 (shown by the dotted box) of the channel 205. The third region 207 can include a majority of the channel 205 in some cases. For example, the third region 207 encompasses the whole channel 205 in this example, except for the first region 210a and the second region 210b at the interfaces with the source and drain respectively. In this example, the third region 207 of the channel 205 includes the interfaces 220a, 220b between the channel and the ferroelectric layers (“Ferroelectric” in the figure). Interfaces 220a, 220b may also be referred to as being on opposite “sides” of the channel 205, and regions 210a and 210b can be referred to as being on opposite “sides” or “ends” of the channel 205, as shown in FIG. 2B. In some examples, the first region 210a and the second region 210b are spaced apart from one another, and the third region 207 of the channel 205 is located between the first region and the second region. The inset of FIG. 2B shows the channel 205 in isometric view, and the first region 210a, the second region 210b, and the third region including the interfaces 220a, 220b between the channel and the ferroelectric layers.

In the example shown in FIG. 2B, the channel 205 is shown as a rectangular prism with straight sidewalls; however, in practice the NC-BCFET may have a channel with tapered sidewalls (i.e., where the channel has a trapezoidal cross-section). For example, the interfaces 220a, 220b can be parallel to one another, and the sidewalls of the channel forming the first and second regions 210a, 210b can be angled to taper in towards one another, such that interfaces 210a, 210b are not parallel with each other.

In some cases, the NCBCFET further includes a first ferroelectric layer in contact with a first side 220a of the channel 205 in the third region 207 of the channel. As shown in FIG. 2B, the first gate layer may be in contact with the first ferroelectric layer, and the first ferroelectric layer may be between the first gate layer and the channel. In some examples, a second ferroelectric layer is in contact with a second side 220b of the channel opposite the first side 220a in the third region 207 of the channel 205. For example, a second gate layer may be in contact with the second ferroelectric layer, and the second ferroelectric layer may be between the second gate layer and the channel 205. In this arrangement, the first and second gate layers are also capacitively coupled with the channel 205, since the ferroelectric layers between the gate layers and the channel are electrically insulating. Since they are capacitively coupled to the channel 205, applying a bias across the gate layers can modulate the electric field in the channel 205, and turn the channel layer “ON” or “OFF,” as shown in FIG. 2C and described further herein.

In the bilayer structures described herein, there are two sets of conduction and valence bands. If tunneling between the layers of the bilayer structure is zero or small, the two sets of conduction and valence bands are degenerate, or nearly degenerate, (e.g., as shown in the “OFF” diagram in FIG. 2C) at zero electric field, and the bands split or separate in energy (e.g., as shown in the “ON” diagram in FIG. 2C) at non-zero electric field. If tunneling between the layers of the bilayer structure is large, the two sets of conduction and valence bands can split at zero field. Therefore, to obtain a larger Figure of Merit (“FOM”), the tunneling between the layers of the bilayer structure should be small. For example, the hybridization energy between the bands due to tunneling can be much smaller (e.g., about 10 times, or even more than 10 times smaller) than the bandgap.

It can be advantageous to find a material for the channel layer of the NC-BCFET structure of FIG. 2B that has a large electric field dependence on its bandgap. Specifically, the change in bandgap ΔEg produced by a change in electric field ΔEF can be used to define an effective thickness teff of the channel:

$$\frac{Δ {E}_{g}}{e Δ E F} ≡ {t}_{e f f}$$

The channel materials and structures described herein advantageously have large changes in energy gap with small applied biases, and can therefore be used to improve NC-BCFETs compared to devices with conventional channel materials.

In one example, a bilayer channel including two atomically thin semiconducting layers described herein has a modulable bandgap that changes strongly with applied electric field, which advantageously increases the effective thickness (t_{eff}) relative to the physical channel thickness (t_{channel}) and thereby increases the figure of merit, t_{eff}/t_{channel}, used to minimize NC-BCFET switching voltage. This larger field-driven bandgap modulation advantageously enables lower-voltage switching and can reduce energy consumption compared to NC-BCFET devices using conventional channel materials such as bilayer graphene.

In another example, inserting a thin or atomically thin tunneling/insulating layer described herein between the two semiconducting layers in the channel of a device reduces, but does not eliminate, interlayer tunneling and hybridization so that the conduction and valence bands remain nearly degenerate at zero field yet split efficiently under a non-zero field, producing a sharper OFF-to-ON transition. By mitigating charge rearrangement that would otherwise screen the field across the channel, the structure preserves strong internal field action and advantageously improves the device switching behavior, while interlayer charge transfer due to tunneling can still occur on time scales relevant to transistor operation. For example, in some cases, the interlayer tunneling can remain substantial with a few meV hybridization, and tunneling times can be picoseconds or shorter. This allows charge to rearrange rapidly on the time scale of device operation.

In a further example, increasing the separation distance between the two semiconductor layers (e.g., into a regime where larger interlayer spacing enhances the electric-field switching effect) improves bandgap closure behavior. Mechanical stability concerns arising from that spacing can be addressed by stabilizing the stack with a tunneling layer (e.g., hexagonal boron nitride (h-BN), sapphire, or hafnia) while retaining the rapid field response. This combination advantageously improves practical device robustness while keeping the advantageous electric-field-sensitive channel behavior needed for low-voltage operation compared to devices with conventional channel materials.

In another example, using the bilayer heterostructures described herein (e.g., h-BN with WSe₂ bilayers, sapphire with MoS₂ bilayers, or hafnia with MoS₂ bilayers) increases the magnitude of bandgap change at relatively low applied fields and can enable complete gap closing in regimes where conventional stacked bilayers do not show gap closing over the same field range. These channel structures therefore advantageously improve device (e.g., NC-BCFET) switching margin and can better meet room-temperature ON/OFF requirements that depend on achieving substantial bandgap modulation, compared to devices with conventional channel materials.

In another example, selecting an asymmetric (non-centrosymmetric) insulating layer, such as polar or low-symmetry hafnia, maintains rapid switching for either field polarity while producing a substantially higher t_{eff}/t_{channel} for a preferred field direction. This directional enhancement advantageously gives a circuit designer an additional degree of freedom to optimize NC-BCFET performance without changing the overall device footprint compared to devices with conventional channel materials.

The structures described herein can also have other advantageous functions, since they allow the bandgap of the semiconductor layer to be modulated by applying an electric field (e.g., voltages to Gate 1 and/or Gate 2 of the NC-BCFET), and achieve a large modulation of the bandgap for small voltages applied to the gates. Modulation of the bandgap can lead to modulation of electrical conductivity and optical properties such as the complex optical conductivity including absorptivity of the heterostructures described herein. Thus, the structures described herein can be used to achieve the functions of other devices. For example, modulating the electrical conductivity of the channel with analog signals applied to one or both gates could achieve the functions of an analog transistor, including use as an amplifier or a signal mixer. Modulating the optical properties of the channel via signals applied to one or both gates could achieve the function of an electro-optical modulator and/or electro-absorption modulator, when the channel is placed within the electric field region of a light wave, which may be propagating in the direction parallel or perpendicular to the channel. The structures described herein can advantageously enable such devices with lower operating voltage and switching energy, and capability for higher frequency operation, than conventional devices.

The thickness of the channel (t_{channel}, tChannel, or “t_channel”) is the thickness of the layers of the channel, for example, when the channel is in a structure sandwiched between surrounding layers. As shown in FIG. 2D, the thickness of the channel (“t_channel”) includes the thickness of first and second semiconductor layers 230 the insulating layer(s) 240, and any bonding distance (e.g., covalent or van der Waals bond lengths) between the layers of the channel and the surrounding layers (e.g., between the channel and the “Ferroelectric” layers in the NC-BCFET structure shown in FIG. 2B).

The switching voltage of the NC-BCFET can be minimized when the dimensionless quantity

$$Figure of Merit ≡ \frac{{t}_{e f f}}{{t}_{C h a n n e l}}$$

is maximized.

Additionally, room-temperature operation with a high ON/OFF ratio can require the range of bandgap modulation (ΔE_{g}) to be at least 250 meV and in some cases it can be larger.

Although it has been reported that bilayer graphene has a bandgap that depends on the electric field, the maximum modulation of the bandgap is approximately 250 meV, and the Figure of Merit (FOM) is approximately 0.1, which is relatively small compared to the channel materials and structures described herein. Moreover, some conventional sources suggest that a topological insulator layer with strong spin-orbit coupling, such as bismuthene, should have a large FOM. However, in contrast to the conventional sources, it has been found that some topological insulator layers consisting of single layers of single elements of Group IVA or Group VA of the periodic table have low FOMs.

FIGS. 2E-2J show schematic cross-sections of some examples of structures that can be used in NC-BCFET devices.

FIG. 2E shows a structure similar to the structure shown in the NC-BCFET in FIG. 2B, including the two gate layers (“Gate 1” and “Gate 2”) and the two ferroelectric (“ferroelectric”) layers surrounding the channel layer 205, which is electrically in contact with the source and drain. In some cases, the source (“Source”) and drain (“Drain”) regions are formed from the channel 205, for example by doping the channel in the source and drain regions n-type or p-type. FIG. 2E also shows a substrate coupled to one of the gate layers (“Gate 2”). For example, the “Gate 2” layer can be deposited on the substrate, the ferroelectric layer can be deposited on the “Gate 2” layer, and the channel layer can be deposited on the ferroelectric layer. In some cases, after the channel is deposited, then the source and drain regions can be doped n-type or p-type. The ferroelectric layers and the gate layers in the structure shown in FIG. 2E overhang beyond the channel 205 and under and over the source and drain regions. In general, the source and drain may be metal, or doped semiconductor, or they may be regions of the channel material itself, which are made conductive through doping.

The doping of the semiconductor layers within the channel 205 can be n-type or p-type. In some cases, the doping of the semiconductor layers is chosen to make the channel region n-type or p-type and form a barrier to conduction that is respectively lower for electrons or lower for holes. In some cases, the semiconductor layers in regions of the channel 205 close to the contacts (e.g., the source and/or drain) can be doped n-type or p-type, even in cases where the majority of the channel is not intentionally doped, or is doped with a different polarity. In some cases, the semiconductor layers in regions of the channel 205 near the contacts are heavily doped n-type or p-type (e.g., greater than 10¹⁸ cm⁻³, or greater than 10¹⁹ cm⁻³) such that they are highly conducting. This can be advantageous to form ohmic contacts, to reduce the contact resistance, and to reduce the channel resistance, in some cases.

FIG. 2F shows a structure similar to the structure shown in the NC-BCFET in FIG. 2E, where the ferroelectric layer at the top of the device (in contact with “Gate 1”), on the opposite side of the channel 205 than the substrate, is approximately the same width as the channel 205 in the lateral direction between the source and the drain. The other ferroelectric layer (in contact with “Gate 2”), between the substrate and the channel 205, extends beyond the channel under the source and drain regions in this example.

In the example shown in FIG. 2F, the “Gate 2” layer on the substrate extends beyond the ferroelectric layer adjacent to it, and the “Gate 2” layer extends laterally beyond the rest of the device on the right-hand side of the figure. All four of the contacts, “Source,” “Drain,” “Gate 1,” and “Gate 2” can be accessed from the top (opposite side from the substrate) in this example. This can be advantageous to couple electrical connections (e.g., wire bond pads, or surface mount pads) to the contacts of the device. In other examples (e.g., in FIG. 2E), contact to the “Gate 2” layer can be made through a conductive substrate, or vias (not shown) through the structure.

FIG. 2G shows a structure similar to the structure shown in the NC-BCFET in FIG. 2E, where the ferroelectric layer at the top of the device, on the opposite side of the channel 205 than the substrate, is narrower than the channel 205 in the lateral direction between the source and the drain. The other ferroelectric layer, between the substrate and the channel 205, extends beyond the channel under the source and drain regions in this example. In an alternative example (not shown), both ferroelectric layers can be narrower than the distance between the source and the drain.

The gate layers (“Gate 1” and “Gate 2”) in the structures shown in FIGS. 2B and 2E-2G can be metal layers, or highly doped semiconductor layers, or other highly conductive material. For example, the gate layer closest to the substrate (“Gate 2”) can be an epitaxially grown metal or doped semiconductor layer and then a metal contact (or bond pad) can be deposited on the “Gate 2” layer (e.g., on the right-hand side of FIG. 2F where the “Gate 2” layer is exposed, or into a via etched down to “Gate 2”).

Metal contacts can be deposited on the gate, source, and/or drain layers of the structures in FIGS. 2E-2G. In the structure in FIG. 2E, the substrate can be conductive (e.g., be a metal, or a highly doped semiconductor) and the bottom gate contact (to “Gate 2”) can be made by depositing metal on the opposite side of the substrate from the “Gate 2” layer. In other cases, one or more vias can be etched through the structure to expose the “Gate 2” layer and metal can be deposited from the top for the “Gate 2” contact. Contacts to the source and drain can be made by creating one or more vias through the “Gate 1” and top ferroelectric layers, or by depositing metal on the side(s) of the structure. In the case of depositing metal on the sides of a mesa structure, it can be advantageous to have tapered mesa side walls to allow metal deposition from the top down. Insulating regions can also be formed or deposited on other layers (e.g., on the sides of the “Gate 1” and “Gate 2” layers) to prevent shorting. FIGS. 2F and 2G show examples of different mesa structures, where the “Gate 1” and top ferroelectric layer have been etched to expose the source and drain. Furthermore, as described above, all four of the contacts for the structure in FIG. 2F are exposed to the top of the structure, and metal contact layers can be deposited on all of these from the top. In FIG. 2G, “Gate 1,” the source, and the drain are accessible from the top, and the “Gate 2” contact can be made through a conductive substrate, or by etching vias through the structure to contact the “Gate 2” layer from the top.

In some cases, the NC-BCFET structures shown in FIGS. 2B and 2E-2J can further include additional layers. For example, an epitaxial buffer layer can be included between the substrate and an epitaxially deposited “Gate 2” or ferroelectric layer. The structures can further include insulating or encapsulation layers (not shown) on top of the structures. For example, after metal contacts are deposited, then a conformal insulating or encapsulation layer can be deposited to protect the layers of the device and/or the metal contact layers. In some cases, windows can be etched into the insulating or encapsulation layers to expose the contacts, in order for electrical connections to be made to the device.

The structures shown in FIGS. 2E-2G can be integrated into a circuit, or an electrical system, for example, they can be bonded to an integrated circuit (e.g., a printed circuit board). For example, the substrate can be bonded to the integrated circuit, or the device can be flip-chip bonded in the case of a surface mount device (SMD). Wire bonds between the device and other components of the circuit can also be made, in some cases. In some cases, the substrates shown in the structures in FIGS. 2E-2G can be removed or thinned, and the device can be bonded to a heat sink. For example, the device could be flip-chip bonded onto a patterned substrate (e.g., patterned with electrically conductive traces aligned with the contacts of the device) to make electrical connections to the contacts of the structures, and then the substrate can be thinned or removed (e.g., using chemical mechanical polishing, CMP).

FIGS. 2H-2J show some example portions of the NC-BCFETs described herein (e.g., those shown in FIGS. 2E-2G), including the channel 205, the source and the drain. The channel 205 includes two atomically thin first and second semiconductor layers 230a, 230b (e.g., each having a thickness of about a monolayer, or from about 1 Å to about 20 Å) and an insulating layer or tunneling layer 240 in between. The heterostructures in FIGS. 2H-2J are similar to the structure shown in FIG. 2D and described with various examples throughout this disclosure. The semiconductor layers 230a, 230b can both be in contact with the source and the drain, or one of the semiconductor layers 230a, 230b can be in contact with the source and the other semiconductor layer 230a, 230b can be in contact with the drain. In some cases, one of the semiconductor layers 230a, 230b is in contact with both the source and the drain and the other of the semiconductor layers 230a, 230b is in contact with neither the source nor the drain.

FIG. 2H-2J show some examples of the options described above. FIG. 2H shows semiconductor layers 230a, 230b both in contact with the source and the drain. FIG. 2I shows semiconductor layer 230a in contact with the source and not the drain, and semiconductor layer 230b in contact with the drain and not the source. There are gaps between semiconductor layer 230a and the source and between semiconductor layer 230b and the drain in this example. The gaps can be various dimensions, such as from less than 10% to greater than 30% of the length of the channel (between the source and the drain), or from less than about 1 nm to greater than about 1 mm, or from less than about 1 nm to about 10 μm, or from less than about 1 nm to about 100 nm. FIG. 2J shows semiconductor layer 230a in contact with both the source and the drain, and semiconductor layer 230b in contact with neither the source nor the drain (since gaps exist on both sides of semiconductor layer 230b). Not to be limited by theory, the bilayer heterostructure of channel 205 can behave like a single material, and therefore not all portions need to be in contact with the source and the drain to conduct current between the source and the drain.

FIG. 2K shows illustrative example graphs of electric potential versus perpendicular distance during OFF-state and ON-state operation of an example NC-BCFET of FIG. 2B. The example perpendicular distance (i.e., “vertical distance”) in FIG. 2K is measured along an axis between Gate 2 and Gate 1 that is approximately perpendicular to a major direction of current flow in the channel 205 (from the source to the drain). It will be understood that an electric potential energy qV is a product of the charge q and an electric potential V. Moreover, the potential energy of an electron with charge −e in a potential V is −eV. During the OFF-state operation of an example NC-BCFET of FIG. 2B, the magnitude of the electric potential is constant, at zero, throughout all perpendicular distances from Gate 2 as shown by the dashed line. During the OFF-state operation of an example NC-BCFET of FIG. 2B, the magnitude of the electric potential within the first ferroelectric layer (adjacent to “GATE 2”) increases with increasing perpendicular distance from Gate 2, the magnitude of the electric potential within the second ferroelectric layer (adjacent to “GATE 1”) increases with increasing perpendicular distance from Gate 1, and the magnitude of the electric potential within the channel decreases with increasing perpendicular distance from Gate 2, as shown by the solid line in the figure.

N-type NC-BCFET operation may be accomplished by using a n-type heterostructure channel material and by applying zero volts to the source and Gate 1, and a positive voltage to the drain. Gate 2 functions as a control gate in this case. When zero volts is applied to Gate 2, the electric potential is identical at all points along the perpendicular distance axis (dashed line), and no electric field is applied to the channel, achieving the OFF-state operation. When a positive voltage is applied to Gate 2, the electric potential within each of the first and second ferroelectric regions increases with increasing perpendicular distances from Gate 2 and decreases with increasing distance from Gate 2 within the heterostructure channel material (solid line). The bandgap is reduced due to the electric field across the channel, achieving the ON-state operation. In other cases, the voltage applied to Gate 1 is non-zero, and the voltage applied to Gate 2 is greater than the voltage applied to Gate 1 to achieve the ON-state.

P-type operation of the NC-BCFET may be accomplished by using a p-type heterostructure channel material and applying a negative voltage to the drain. In the case of a symmetric NC-BCFET structure, zero volts is applied to Gate 1 and the source, and a negative voltage applied to Gate 2 to achieve the ON-state. In other cases, the voltage applied to Gate 1 is non-zero, and the voltage applied to Gate 2 is less than the voltage applied to gate 1 to achieve the ON-state. For a symmetric structure, it is unimportant if Gate 1 and Gate 2 are interchanged. If the NC-BCFET is asymmetric, such that with equal voltages on Gate 1 and Gate 2 the bands are already split, such that conduction band c2 is already lower in energy than conduction band c1, and valence band v2 is lower in energy than valence band v1, then zero volts can be applied to Gate 2 and the source, and Gate 1 will operate as a control gate, where a negative voltage applied to Gate 1 will reduce the barrier for injection of a hole into the highest valence band v1 and create the ON-state. In other cases, the voltage applied to Gate 1 is non-zero, and the voltage applied to Gate 2 is less than the voltage applied to gate 1 to achieve the ON-state.

Due to the negative capacitance of the ferroelectric material, the electric field between Gate 1 and channel 205 and the electric field between Gate 2 and channel 205 have the same direction, which is opposite to the direction of the electric field in the channel.

The purpose of the ferroelectric layers in combination with the channel layer 205, is to amplify the electric field across the channel layer 205, i.e. the electric field across the channel layer for a particular difference in the voltages at the first and second gates should be larger than it would have been had the ferroelectric layers instead been conventional dielectrics.

The ferroelectric layers and channel 205 should be chosen such that the total capacitance between Gate 1 and Gate 2, i.e. the series capacitance of the first ferroelectric layer, the channel 205, and the second ferroelectric layer is positive. The ferroelectric layers act as negative capacitors, where the capacitances of the ferroelectric layers are C_{FE1}<0 and C_{FE2}<0. The capacitance of channel 205 is C_{CH}>0. The total series capacitance Cₜₒₜₐₗ between gate 1 and gate 2 is then given by:

$$\frac{1}{{C}_{t o t a l}} = \frac{1}{{C}_{CH}} + \frac{1}{{C}_{F E 1}} + \frac{1}{{C}_{F E 2}} ,$$

and the condition that Cₜₒₜₐₗ>0 is met when

$${C}_{C H} < {[ \frac{1}{{C}_{F E 1}} + \frac{1}{{C}_{F E 2}} ]}^{- 1} .$$

This condition ensures that the electric field in the direction perpendicular to the first and second semiconductor planar layers is a single-valued function of the difference between the voltages at the first and second gates, i.e. there is no hysteresis.

In order to achieve a large amplification of the electric field, the absolute magnitude of the combined capacitance of the ferroelectric layers

$${[ \frac{1}{{C}_{F E 1}} + \frac{1}{{C}_{F E 2}} ]}^{- 1}$$

can be chosen to be comparable in magnitude to, but not larger than, C_{CH}.

The tunneling layer can be chosen such that the tunneling of electrons occurs on a timescale which is faster than the typical timescales of device operation, which, for modern transistors, may be as small as picoseconds. The characteristic tunneling time tₜᵤₙₙₑₗ may be estimated from the hybridization energy α for the energy bands in semiconductor layer 1 and layer 2 from

$${t}_{tunnel} = \frac{ℏ}{Δ}$$

where ℏ is the reduced Planck's constant. The requirement tₜᵤₙₙₑₗ<1 ps can be achieved with a small hybridisation energy Δ>0.7 meV.

FIG. 2L is a conceptual drawing showing relationships between conduction (electron) energy bands (c1, c2) and valence (hole) energy bands (v1, v2) of the first and second semiconductor layers 230a and 230b of a symmetric channel 205 of the NC-BCFET (e.g., as shown in FIGS. 2B-2J) as a function of momentum, when the device is in an OFF-state (shown on left) and when the device is in an in an ON-state (shown on the right). As used herein, “symmetric” means that the channel structure is identical upon a mirror operation about a plane parallel to the channel, and possibly an additional translation operation, and as used herein, “asymmetric” does not have this symmetry. (In non-technical language, “symmetric” means it is the same structure if you flip it upside-down.) In terms of operation, as used herein, “symmetric” means the response of the bandgap to the electric field does not depend on the direction of the electric field, only its magnitude. As used herein, “asymmetric” means that the change in bandgap is different for different directions of the electric field. The structures calculated herein are symmetric, with the exception of two asymmetric structures: polar hafnia and low-symmetry hafnia (FIGS. 20B and 20C).

FIG. 2L conceptually shows that the first conduction and valence bands (c1, v1) can be primarily associated with the first semiconductor layer 230a, and the second conduction and valence bands (c2, v2) can be primarily associated with the second semiconductor layer 230b, as described above. FIG. 2L also conceptually shows changes in the energy gaps between conduction (electron) (c1, c2) energy bands and valence (hole) energy bands (v1, v2) and a source chemical energy potential (e.g., the Fermi level of the source) when the device is in an OFF-state (shown on left) and in an ON-state (shown on the right). In the OFF-state, Gate 1 has a gate-to-source voltage V_{Gate1,S}=0, and Gate 2 has a gate-to-source voltage V_{Gate2,S}=0. In the ON-state, Gate 1 has a gate-to-source voltage V_{Gate1,S}=0, and Gate 2 has a gate-to-source voltage V_{Gate2,S}>0.

FIG. 2L conceptually shows that, in a symmetric device, in the ON-state, the second conduction energy band c2 is closer to the source chemical energy potential than either of the first conduction bands c1 and c2 is, in the OFF-state. In an example symmetric N-type NC-BCFET, the turn-off voltage between Gate 1 and Gate 2 is zero. During OFF-state operation, the energy bands of the first semiconductor layer 230a and the second semiconductor layer 230b are nearly degenerate, and the source chemical potential is such that there is an energy gap between the conduction bands c1 and c2 and the source chemical energy potential. In an example symmetric N-type NC-BCFET, the turn-on voltage between Gate 1 and Gate 2 is positive. During ON-state operation, the perpendicular electric field in the material causes energy bands of the first semiconductor layer 230a and the second semiconductor layer 230b to split. In this example, this reduces the energy gap between the conduction band c2 and the source chemical potential, lowering the barrier to inject electrons from the source into c2 and enabling current flow and ON-state operation.

FIG. 2M is a conceptual drawing showing relationships between conduction (electron) energy bands (c1, c2) and valence (hole) energy bands (v1, v2) of the first and second semiconductor layers 230a and 230b of a asymmetric channel 205 of the NC-BCFET of FIG. 2B as a function of momentum, when the device is in an OFF-state (shown on left) and when the device is in an ON-state (shown on the right). The first conduction and valence bands (c1, v1) can be primarily associated with the first semiconductor layer 230a, and the second conduction and valence bands (c2, v2) can be primarily associated with the second semiconductor layer 230b. FIG. 2L also conceptually shows changes in the energy gaps between energy bands (c1, c2) and valence (hole) energy bands (v1, v2) and a source chemical energy potential (e.g., the Fermi level of the source) when the device is in an OFF-state (shown on left) and in an ON-state (shown on the right). In the OFF-state, Gate 1 has a gate-to-source voltage V_{Gate1,S}=0, and Gate 2 has a gate-to-source voltage V_{Gate2,S}=0. In the ON-state, Gate 1 has a gate-to-source voltage V_{Gate1,S}=0, and Gate 2 has a gate-to-source voltage V_{Gate2,S}>0.

FIG. 2M conceptually shows that, in a symmetric device, in the ON-state, the second conduction energy band c2 is closer to the source chemical energy potential than either of the first conduction bands c1 and c2 is, in the OFF-state. In an example asymmetric N-type NC-BCFET, the turn-off voltage is zero. During OFF-state operation, the energy bands of the first semiconductor layer 230a and the second semiconductor layer 230b are nearly degenerate, and the source chemical potential is such that there is an energy gap between the conduction bands c1 and c2 and the source chemical energy potential. In an example asymmetric N-type NC-BCFET, the turn-on voltage is positive. During ON-state operation, the perpendicular electric field in the material causes energy bands of the first semiconductor layer 230a and the second semiconductor layer 230b to split. In this example, this reduces the energy gap between the source chemical potential and conduction band c2, lowering the barrier to inject electrons from the source into c2 and enabling current flow and ON-state operation.

The example NC-BCFETs of FIGS. 2B-2J can switch between an ON-state and an OFF-state by modulating the band gap energy of the channel 205. As explained above, the band gap energy separates a conduction band energy, occurring in one of the first and second semiconductor material layers 230a, 230b, and a valence band energy, occurring in the other one of the first and second semiconductor material layers 230a, 230b. During operation of the NC-BCFET, a first voltage is applied to Gate 1, and a second voltage is applied to Gate 2. During the OFF-state, at least one of the first voltage and second voltages is adjusted, such that a first electric field magnitude across the channel 205 in a perpendicular direction between Gate 1 and Gate 2 causes a first band gap energy across the channel 205. During the ON-state, at least one of the first voltage and the second voltage is adjusted, such that a second electric field magnitude across the channel 205 in a perpendicular direction between Gate 1 and Gate 2 causes a second band gap energy across the channel 205.

In some cases, the difference (“E_diff”) between the first band gap energy during the OFF-state and the second band gap energy during the ON-state is at least 240 meV. In some cases, the difference between the first electric field magnitude during the OFF state and the second electric field magnitude during the ON-state is no more than 0.25 V/Angstrom. The bilayer heterostructure materials, structures, and devices described herein can advantageously meet these requirements. An ON/OFF band gap difference E_diff=240 meV corresponds to an ON/OFF ratio given by exp(E_diff/kT)>13,000, where 13,000 is the ON/OFF ratio for an end-of-roadmap benchmark CMOS low voltage device, and kT is the thermal energy at room temperature. The breakdown strength of most common thin dielectric materials is less than 0.25 V/Angstrom, and so it is an approximate upper limit to the electric field that can be applied before a device breaks down. Thus, the example NC-BCFETs of FIGS. 2B-2J are compatible with CMOS benchmarks.

For example, the modeled bandgap changes of many of the bilayer heterostructures shown in FIGS. 7A-8, 12A-12B, 14A-14B, 16A-16B, 18A-18B, 19A-19B, and 21A-23B show bandgap changes of more than 240 meV with applied electric fields less than 0.25 V/Angstrom. In other words, they have high FOMs (t_{eff}/t_{channel}). As described above, NC-BCFET devices with channel materials having a high FOM can advantageously have lower-voltage switching and reduced energy consumption compared to NC-BCFET devices using conventional channel materials (such as bilayer graphene). Devices with bilayer heterostructure channels having the high FOMs can also have improved switching margin and can better meet room-temperature ON/OFF requirements. As described above, the large bandgap changes of the bilayer heterostructures described herein with small applied electric fields can also be beneficial for other types of semiconductor devices such as analog transistors and opto-electronic modulators.

The present disclosure describes new bilayer structures with heterostructure materials that include two atomically thin semiconducting layers separated by a thin or an atomically thin insulating layer. In some cases, the semiconductor layers are atomically thin layers that are thin enough that the electrons in the layers are substantially confined in a 2D plane. In such cases, the electrons in a two-dimensional subband within the semiconductor layers can move in the 2D plane, but are inhibited from moving out of the plane. In atomically thin layers, the spacing between the subbands in the out-of-plane direction is comparable to or smaller than the semiconducting bandgap. For example, in atomically thin layers, the spacing between the subbands in the out-of-plane direction is about one-fifth, about one-half, or about the semiconducting bandgap, or larger than the semiconducting bandgap. The subbands may be singly or multiply degenerate, for example, they may have spin and/or valley degeneracies.

For example the bilayer structures described herein can include one or more atomically thin layers with thicknesses from about a monolayer to about 10 monolayers, about a monolayer, about two monolayers, less than about 5 monolayers, less than about 10 monolayers, less than one unit cell, from 1 to 2 unit cells, about one unit cell, about half of one unit cell, less than about one unit cell, from less than about one unit cell to about two unit cells, or from about half of one unit cell to about two unit cells, from about 1 Å to about 20 Å, less than about 20 Å, less than about 10 Å, or less than about 5 Å. The term “monolayer” as used herein refers to a layer having a thickness of one layer of atoms and/or one formula-unit layer (e.g., a single-element monolayer such as Pb, or a multi-element monolayer such as an MX₂ layer in which one formula-unit layer is a metal atomic plane sandwiched between chalcogen atomic planes, e.g., MoS₂). The insulating layer can be atomically thin, or can be thin and have a thickness from about a monolayer to about 50 monolayers, about a monolayer, about 5 monolayers, less than about 10 monolayers, less than about 20 monolayers, less than about 50 monolayers, from 1 to 10 unit cells, about one unit cell, about 5 unit cells, from about 5 Å to about 100 Å, less than about 100 Å, from about 5 Å to about 50 Å, less than about 50 Å, less than about 25 Å, or less than about 10 Å. Note that a thickness of one unit cell, can be interpreted as a thickness equivalent to one unit cell of a layered parent material with multiple unit cells. The entire thickness of the bilayer heterostructure including two atomically thin semiconductor layers and the insulator between them can be from about 1 Å to about 150 Å, from about 2 Å to about 50 Å, from about 10 Å to about 50 Å, or from about 10 Å to about 30 Å. The entire thickness of the channel layer including two atomically thin semiconductor layers and the insulator between them can be from about 1 Å to about 150 Å, from about 2 Å to about 50 Å, from about 10 Å to about 50 Å, or from about 10 Å to about 30 Å.

The bilayer structures described herein have exceptional responses to electric fields compared with those of materials such as bilayer graphene or topological insulator layers. It is contemplated that the new heterostructure materials described herein, when used as the channel layer in the NC-BCFET structure of FIG. 2B, for example, can provide improvements to electronic devices, such as improved transistor switching at lower voltage.

The bilayer structures described herein include heterostructure materials with two atomically thin semiconductor layers separated by an insulator layer. The insulator layer can be a thin vacuum, or an atomically thin insulator layer. Each of the semiconductor layers is atomically thin and can be bonded to the insulator layer and to surrounding layers with van der Waals (vdW) forces, covalent bonds, or other types of forces. Such bilayer structures can be composed of two semiconductors whose electronic structures can each be described by a single (in some cases, multiply degenerate) two-dimensional subband. In some cases, the thicknesses of the layers making up the heterostructure material are tailored to be thin enough to promote some electron tunneling between the semiconductor layers, but thick enough such that the amount of tunneling between the two semiconductor layers is not so large that it promotes strong screening of the electric field which reduces the figure of merit. In some cases, the characteristic hybridization energy of the bilayer structures of the channel is less than about 1/10 of the bandgap of the semiconductor materials, for example, less than about 10 meV, less than about 100 meV, less than about 150 meV, less than about 200 meV, or from about 50 meV to about 250 meV.

In the bilayer structures described herein, an application of an electric field can shift the potential of the two semiconductor layers relative to one another, raising the potential of one semiconductor and lowering the potential of the other. In some cases, this can bring the valence band of the first semiconductor closer to the conduction band of the second semiconductor, to reduce or close the bandgap. In the bilayer structures described herein, the rearrangement of charge, which would screen the electric field across the structure, is mitigated or prevented. For example, the bilayer structures described herein can include atomically thin semiconductors that can be hybridized in an electric field, and a tunnel barrier separating the semiconductors thick enough to reduce tunneling and hybridization between the two semiconductors to negligible levels. In some cases, the atomically thin semiconductors also do not include multiple sidebands. The bilayer structures described herein can be used in a nanoscale electronic device (e.g., as a channel in a transistor, such as an NC-BCFET), and the entire heterostructure material thickness can be no more than a few nanometers (e.g., from about 10 Å to about 30 Å), which is achievable with atomically thin semiconductors and insulator layers.

The structures described herein, including the atomically thin semiconductor and thin or atomically thin insulator layers, can be fabricated using thin film growth techniques, such as physical vapor deposition (PVD), molecular beam epitaxy (MBE), chemical vapor deposition (CVD, including plasma-enhanced chemical vapor deposition (PECVD) or metal-organic chemical vapor deposition (MOCVD)), atomic layer deposition (ALD), pulsed laser deposition (PLD), or mechanical transfer of layers. In some cases, epitaxial registry of the atoms in adjacent layers is not necessary. In some cases, van der Waals molecular beam epitaxy may be used to form thin-film heterostructures with atomically sharp van der Waals heterointerfaces in the vertical direction without atomic registry in the lateral directions, as described further herein. In some cases, the bilayer structures described herein can be used as channel layers of transistors (e.g., NC-BCFETs) and semiconductor device processing techniques, such as photolithography, etching, and metal contact deposition, can be used to fabricate the devices.

There are numerous techniques that can be utilized for the controlled growth or deposition (e.g., epitaxy, or epitaxial deposition) of the 2D and 3D crystalline materials and structures described herein. For example, three of the most widely deployed thin-film deposition techniques are chemical vapor deposition (CVD), molecular beam epitaxy (MBE), and atomic layer deposition (ALD).

The materials and structures described herein (e.g., the structures shown and modelled in FIGS. 2A-23B) can be formed or deposited on a substrate using the thin-film deposition techniques. In some cases, the films and structures are deposited epitaxially on a single crystal substrate. For example, the materials and structures described herein can be coupled to substrates including Si, SiO₂, Al₂O₃ (e.g., sapphire), BN (e.g., h-BN), or SiC.

Chemical vapor deposition (CVD) growth techniques based upon thermal decomposition of volatile precursors in a heated reactor chamber (“hot-wall” CVD) or a heated substrate (“cold-wall” CVD) can be used to form or deposit the materials and structures described herein (e.g., the structures shown and modelled in FIGS. 2A-23B). In some cases, plasma-enhanced CVD (PECVD) can be used to enable lower temperature decomposition of precursors containing elements of the materials described herein. In some cases, some or all of the precursors are volatile metalorganic species, and a metal-organic CVD (MOCVD) technique can be used to form the materials and structures described herein. For example, reactant species containing the elements in the materials and structures described herein can flow into a reactor chamber along with a carrier gas (e.g., H₂, N₂, or mixtures) and can be delivered to a substrate where they react to form the desired crystalline materials and structures. The substrate can be heated to from about 500° C. to about 1200° C. (or less than 500° C. for PECVD) and the reactor chamber can contain an environment at moderate pressures (e.g., from about 50 Torr to about 760 Torr). Not to be limited by theory, the elevated substrate surface temperature can drive strong adatom diffusion and thereby enhance crystal quality of the growing film.

CVD and MOCVD can be used to form or deposit the materials and structures described herein with excellent compositional uniformity and controllable doping. For example, trace elements can be intentionally incorporated to create n-type and/or p-type electrically conductive regions. These techniques are also compatible with wafers having at least 300 mm diameters and have been widely deployed for growth of compound semiconductors such as GaAs and GaN, where high throughput and scalability have enabled products in markets such as mobile communications, power electronics, and blue/white LEDs. In some cases, CVD or MOCVD can be used deposit transition metal dichalcogenide (TMD) films such as (Mo,W)(S,Se)₂. For such films, transition metal precursors can include W and Mo carbonyls, amides, alkynes, and inorganic compounds such as MoO₃, MoO₂Cl₂, and WO₃. Chalcogen sources can include solid S and Se, H₂S, H₂Se, and diethyl (S,Se), among others.

MBE is a physical vapor deposition (PVD) process that can be used to form or deposit the materials and structures described herein (e.g., the structures shown and modelled in FIGS. 2A-23B). MBE deposition takes place under ultra-high vacuum (e.g., from about 10⁻⁹ Torr to about 10⁻¹¹ Torr) conditions, where elemental or compound sources including elements of the materials described herein (e.g., metals, chalcogens, dopants) are heated to generate molecular beams that impinge directly on a heated substrate. Refractory elements such as W and Mo can use electron-beam heating to achieve significant fluxes of source material. Elements which exist as molecules in the gas phase (e.g., S and Se) may benefit from special “cracker” cells that are used to create beams of atomic or smaller molecular species that can be used to deposit the materials and structures described herein. Substrate temperatures can be lower in MBE than MOCVD, in some cases. Not to be limited by theory, film growth in MBE can proceed via surface adsorption, diffusion, and incorporation into the growing crystal. The MBE epitaxial growth processes used to deposit the materials and structures described herein can be monitored in-situ using reflection high-energy electron diffraction (RHEED), which can enable real-time feedback of growth rate and surface reconstruction (surface crystal structure).

MBE can be used to form or deposit the materials and structures (e.g., the complex heterostructures) described herein with atomic-layer precision and interface control. MBE may have lower growth rates than MOCVD, however, MBE can be used to form or deposit high quality 2D materials (e.g., graphene, hBN, TMDs) and structures owing to sub-monolayer control, abrupt heterointerfaces, and ease of alloy engineering (e.g., to form Mo₁₋ₓWₓS₂).

ALD is another thin film growth technique that can be used to form or deposit the materials and structures described herein (e.g., the structures shown and modelled in FIGS. 2A-23B) using a cyclic, self-limiting chemical process that alternates exposure of the substrate to precursor A and precursor B (each including one or more elements of the materials described herein), with inert gas purges between each pulse. Reactants can include metal-organic precursors along with oxidants, nitridants, or chalcogen sources, in some cases. Each half-reaction can coat the surface with a monolayer of adsorbed species, which can prevent overgrowth and ensure uniform, conformal films even on surfaces with topology (e.g., rough materials, materials with mesas or holes, or porous materials). ALD of the materials and structures described herein can be done at relatively low deposition temperatures (e.g., less than about 400° C.), which can be advantageous since these processes can be compatible with other processes (e.g., many Si-based semiconductor processes at temperatures below about 400° C.).

ALD growth rates are inherently slow (~1-10 nm/cycle) due to the cyclic nature of the process and film crystallinity can be poor unless accompanied by post-deposition annealing. However, ALD can be used to deposit ultrathin oxides (e.g., Al₂O₃, HfO₂, and ferroelectric insulators) and high-κ dielectrics on 2D materials without causing surface damage. ALD can also be used to deposit crystalline 2D TMD films such as WS₂ and MoS₂, for example using metal-containing precursors with W or Mo (such as metal halides, metal carbonyls, or metal-organic precursors), and a precursor containing sulfur (such as H₂S).

In some cases, a method of forming the NC-BCFET structures described herein (e.g., as shown in FIGS. 2B and 2E-2J) includes growing the entire device stack (gate 1, ferroelectric 1 (i.e., the “ferroelectric” layer adjacent to “Gate 1”), semiconductor 1 (i.e., the semiconductor layer closer to “Gate 1” than “Gate 2”), tunnel layer, semiconductor 2 (i.e., the semiconductor layer closer to “Gate 2” than “Gate 1”), ferroelectric 2 (i.e., the “ferroelectric” layer adjacent to “Gate 2”), and gate 2) layer-by-layer on a substrate using one or more of the thin-film growth techniques listed above. The various layers could all be deposited using the same thin-film growth technique, or using different thin-film growth techniques for different layers. For example, the semiconductor and insulating or tunneling layers of the channel can be deposited using a technique such as ALD or MBE that is capable of depositing atomically thin layers with high quality, and one or both of the gate layers can be deposited using metal evaporation or sputtering.

The various layers of the NC-BCFET structures described herein (e.g., as shown in FIGS. 2B and 2E-2J), including the gate 1, ferroelectric 1, semiconductor 1, tunnel layer, semiconductor 2, ferroelectric 2, and gate 2, can each be epitaxial or non-epitaxial.

For example, some of the layers can be non-epitaxial, and can be high quality, by using van der Waals forces to bond a thin layer to the underlying layer. Some or all of the layer combinations of the structures can be deposited using “van der Waals epitaxy,” in which atomically sharp interfaces are formed in the vertical direction, but there is no necessary atomic registry in the lateral direction.

For example, the transition metal dichalcogenide (TMD) films such as (Mo,W)(S,Se)₂, WSe₂, or MoS₂ have a layered crystal structure in which each atomic sheet is an X-M-X “sandwich” (chalcogen-metal-chalcogen) and adjacent sheets are bonded together by relatively weak van der Waals interactions. This layered crystal structure enables these materials to be deposited layer-by-layer and epitaxial-like growth (e.g., van der Waals epitaxy) can be achieved without requiring strict lattice matching to the underlying substrate. The other materials described herein, such as the pnictogens (group-15 elements), can also have layered crystal structures that are compatible with van der Waals epitaxy. For example, pnictogens with orthorhombic crystal symmetry (e.g., black phosphorus and antimonene) can have layered crystal structures that are compatible with van der Waals epitaxy. In another example, 2D allotropes of group-4 elements (e.g., silicene, germanene, stanine, and plumbene) are structurally analogous to graphene (with a hexagonal honeycomb structure) and can also form atomically thin buckled sheets with weak bonds coupling the sheets together.

As a result, some layers of the structures described herein can be formed using van der Waals epitaxy of layered allotropes of materials (e.g., the TMD materials (e.g., (Mo,W)(S,Se)₂, WSe₂, and MoS₂), pnictogens (e.g., P, As, Sb, and Bi) and group-4 elements (e.g., Si, Ge, Sn, and Pb) described herein), to advantageously form the high-quality, atomically thin layers (for example, about one monolayer thick), even on substrates that would be considered lattice-mismatched in conventional epitaxy.

When forming the NC-BCFET structures described herein (e.g., as shown in FIGS. 2B and 2E-2J), the substrates can be an electrically conducting doped semiconductor or metal, and the substrate itself can act as the gate layer (e.g., “Gate 2” in FIGS. 2E-2G). In other cases, the substrate can be an electrical insulator, on top of which the gate layer is deposited as the first layer. In such cases, electrical contact can be made from the top of the device, for example, by etching through the structure, as described above.

In some cases, a method of forming the NC-BCFET structures described herein (e.g., as shown in FIGS. 2B and 2E-2J) includes forming one or more layers or combinations of layers on separate substrates and physically transferring them to another substrate to form the device structures. For example, van der Waals materials, which can be formed using van der Waals epitaxy of layered allotropes of materials, such as those described herein (e.g., P, As, Sb, Bi, Si, Ge, Sn, Pb, (Mo,W)(S,Se)₂, WSe₂, and MoS₂), are particularly amenable to physical transfer. Additionally, physical transfer of metals, oxide insulators, ferroelectrics, and other materials included in the structures described herein are also possible. These techniques can include exfoliating layers of material (e.g., using an adhesive like tape to overcome the weak interlayer van der Waals forces) and physically transferring them to the substrate.

In some cases, the thicknesses of the layers of the NC-BCFET structures described herein (e.g., as shown in FIGS. 2B and 2E-2J) have a high degree of uniformity and continuity. In some cases, each layer of the structure forms a percolating network over an area of the device. For example, the semiconductor and insulating layers of the channel can each form a percolating network in an area between the source and drain electrodes.

Some examples of the above heterostructure materials which exhibit advantageous electric field effects on their bandgaps include:
1) Monolayer honeycomb lattices of monoelemental semiconductor Si (e.g., silicene), Ge (e.g., germanene), Sn (stannene), Pb (plumbene), As (arsenene), Sb (stilbene or antimonene) and Bi (bismuthene) separated by vacuum (e.g., an 8.5 Å vacuum separation).
2) Monolayer lead (Pb, plumbene) honeycomb lattice semiconductor layers separated by 1, 2, 3, 4, 5, or 11 layers of hexagonal boron nitride (h-BN) insulator. Each layer of h-BN can be one monolayer of BN with a hexagonal arrangement of B and N atoms.
3) Bilayer orthorhombic phosphorus (“black phosphorus”) semiconductor layers separated by 1 layer of h-BN.

In some cases, the bilayer structures described herein can include atomically thin semiconductor or insulator layers with a crystallographic space group P6/mmm, P(3-bar)m1 (e.g., silicene), P63mc (e.g., germanene), or Cmca (e.g., black phosphorus).

In some cases, the bilayer structures described herein can include atomically thin layers of pnictogens. In some cases, the atomically thin layers of pnictogens can include P, As, Sb, or Bi. In some cases, the semiconductor layers of the bilayer structures described herein can include approximately two-dimensional pnictogen materials (e.g., P, As, Sb, Bi) with honeycomb lattices. Pnictogen materials can have indirect band gaps from about 0.4 eV to about 1.4 eV. For example, a bilayer structure described herein can include two layers of atomically thin pnictogen materials separated by a thin or atomically thin insulator layer. The insulator layer can contain a material with suitable electronic properties and a thickness to promote some electron interaction but reduced tunneling between the two semiconductor layers.

Conventional NC-BCFETs can include staggered hexagonal monolayers in their channels. However, topological insulator layers consisting of single layers of single elements of Group IVA or Group VA of the periodic table can have low FOMs (t_{eff}/t_{channel}). In contrast to conventional staggered hexagonal single-layer NC-BCFET channel materials, the materials and structures described herein include bilayers of the semiconductor materials described herein (e.g., in Tables 1-5 below). These bilayer semiconducting layers are separated by a tunneling layer (e.g., vdW stacks) and can more effectively switch between “ON” and “OFF” states at smaller voltages compared to conventional choices such as graphene bilayers.

As shown in FIG. 2C, the semiconductor bilayer structures described herein have a semiconducting gap when in the “OFF” state. When the gate voltage is applied, the electronic bands of the structure will split or separate and become overlapped. The gap will be closed once sufficient electric field strength is applied, as shown in the “ON” state.

The inventors developed a workflow for discovering electric field-sensitive materials. The inventors demonstrate a workflow based on Density Functional Theory (DFT) calculations to study the electronic behavior of two-dimensional materials, aiming to investigate the response of bilayer stacks to an applied electric field.

FIGS. 3A-3D are figurative views of different categories of material structures studied. FIG. 3A represents an illustrative monolayer (1L) including one atomically thin semiconductor layer 250a. FIG. 3B represents an illustrative conventional bilayer stacking (2L-CONV) including two atomically thin semiconductor layers 250b, 250c. FIG. 3C represents an illustrative reversed bilayer stacking (2L-REV) including two atomically thin semiconductor layers 250d, 250e, where the alignment between the layers 250d and 250e is different from the alignment of layers 250b and 250c. FIG. 3D represents an illustrative bilayer stacking with tunneling (2L+TUNNEL) including two atomically thin semiconductor layers 250f and 250g separated by a thin or atomically thin insulator layer 260.

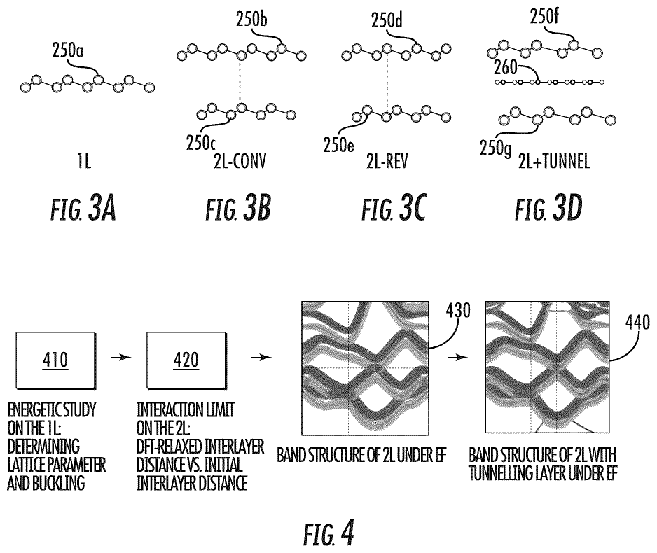

FIG. 4 is an illustrative drawing representing a workflow based on DFT calculations to identify electric field-sensitive heterostructure materials. Block 410 represents an energetic study on a 1L material (e.g., as shown in FIG. 3A) to determine lattice parameters and buckling. Block 420 represents a study of the interaction limit on a 2L material (e.g., as shown in FIG. 3B or 3C) to determine DFT-relaxed interlayer distances versus initial interlayer distances. Block 430 represents a DFT study of the band structure of a 2L material (e.g., as shown in FIG. 3B or 3C) under an electric field. Block 440 represents a DFT study of the band structure of a 2L material with a tunneling layer under an electric field (e.g., as shown in FIG. 3D).

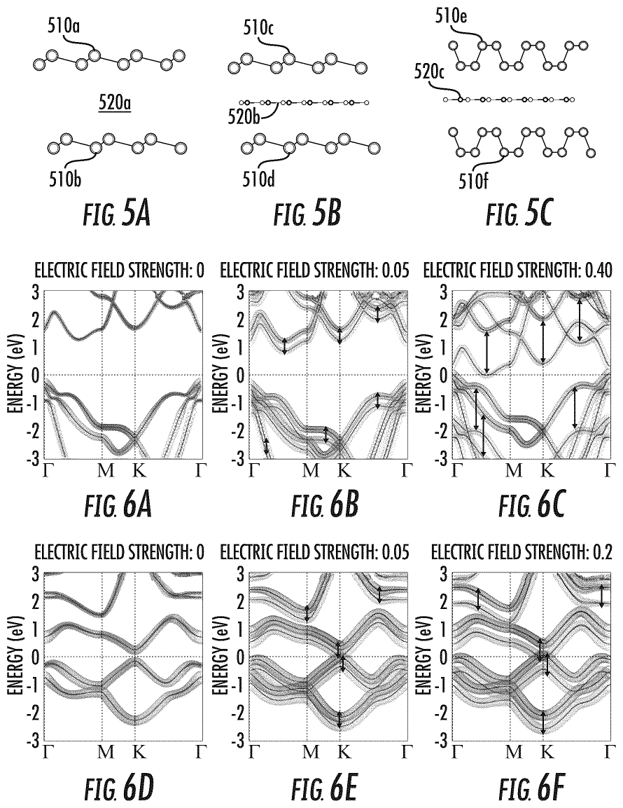

Three example material stack configurations are shown in FIGS. 5A-5C. FIG. 5A is an illustrative drawing that represents bilayer hexagonal monoelemental layers 510a, 510b separated by a vacuum layer 520a. FIG. 5B is an illustrative drawing that represents bilayer hexagonal monoelemental layers 510c, 510d with a tunneling layer 520b. FIG. 5C is an illustrative drawing that represents bilayer black phosphorus (orthorhombic symmetry) 510e, 510f with a tunneling layer 520c.

Note that the atomic positions are not necessarily to scale in the depiction of the semiconductor layers in the figures herein, e.g., in FIGS. 3A-3D and FIGS. 5A-5C. The semiconductor layers shown in the figures can include any of the materials described herein, including those with honeycomb lattices, or other crystal symmetries.

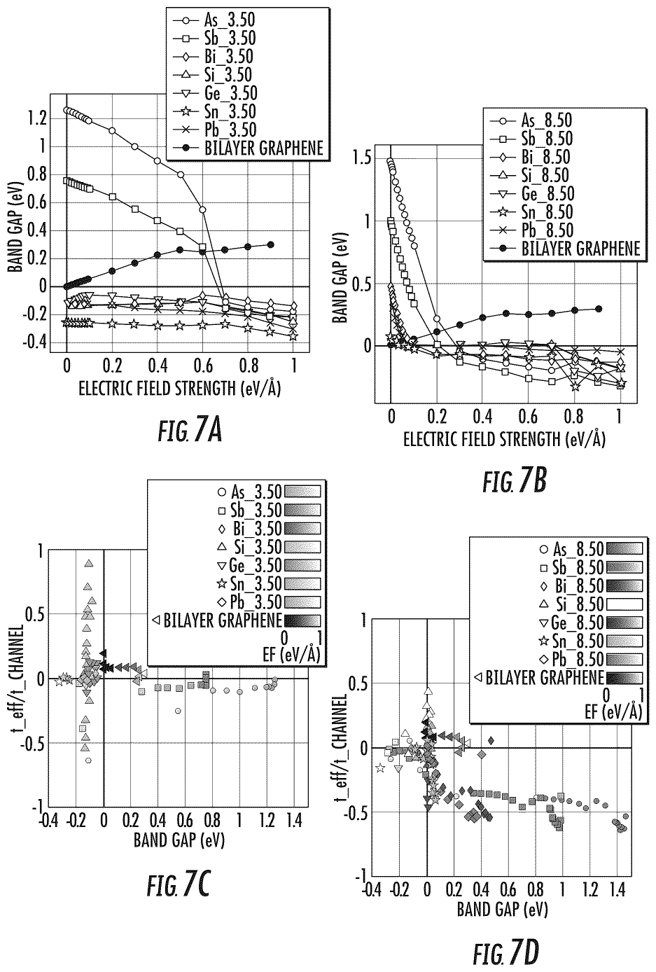

For all swept IVA and VA elements, the inventors showed that bilayer Pb, As, Sb and Bi have semiconducting band gaps greater than about 0.4 eV and present rapid electric field switch behavior. FIGS. 6A-6F show DFT results with energy (eV) on the vertical axis and momentum on the horizontal axis. FIG. 6A is an illustrative drawing showing a DFT result indicating electronic band structure for electric field strength 0 eV/Å for bilayer stacks with respect to applied electric field for bilayer arsenene (As) separated by 8.5 Å. FIG. 6B is an illustrative drawing showing DFT results indicating electronic band structure for electric field strength 0.05 eV/Å for bilayer stacks with respect to applied electric field for bilayer arsenene (As) separated by 8.5 Å. FIG. 6C is an illustrative drawing showing DFT results indicating electronic band structure for electric field strength 0.4 eV/Å for bilayer stacks with respect to applied electric field for bilayer arsenene (As) separated by 8.5 Å. FIG. 6D is an illustrative drawing showing DFT results indicating electronic band structure for electric field strength 0 eV/Å for bilayer plumbene (Pb) separated by 8.5 Å. FIG. 6E is an illustrative drawing showing DFT results indicating electronic band structure for electric field strength 0.05 eV/Å for bilayer plumbene (Pb) separated by 8.5 Å. FIG. 6F is an illustrative drawing showing DFT results indicating electronic band structure for electric field strength 0.2 eV/Å for bilayer plumbene (Pb) separated by 8.5 Å. The dark gray and light gray circles on the band lines represent valence and conduction bands including states from both the contributions from the bottom layer and top layer. The application of an electric field causes splitting of the bands of the bilayer structure, as shown by the bands with the dark gray and light gray circles in FIGS. 6B, 6C, 6E, and 6F compared with the single bands shown in FIGS. 6A and 6D.

In some cases, in the presence of an electric field, the valence and conduction bands will each split into an upper band and a lower band, and the states of one of the split bands (e.g., the upper band) will be associated primarily with, i.e. have charge density which is primarily located on, one of the semiconductor layers (e.g., the top layer) and the states of the other split band (e.g., the lower band) will be associated primarily with the other semiconductor layer (e.g., the bottom layer). This is shown, for example, in FIGS. 6B, 6C, 6E, and 6F, wherein the fraction of the charge density of the states which resides on the first (or second) layer is shown as light gray (or dark gray) with the saturation representing the degree to which the charge density is segregated to one layer. There is generally some fraction of states associated with both of the semiconductor layers in each of the upper and the lower split bands. However, in some cases the FOM can be improved by having a large majority (e.g., greater than 60%, greater than 70%, greater than 80%, greater than 90%, greater than 95%, or greater than 99%) of the states of one of the split bands be associated with one of the semiconductor layers, and a large majority (e.g., greater than 60%, greater than 70%, greater than 80%, greater than 90%, greater than 95%, or greater than 99%) of the states of the other split band be associated with the other semiconductor layer, upon application of an electric field.

The inventors have defined a unitless parameter t_eff/t_channel (t_{eff}/t_{channel}) to assess the electric field response power, where t_eff (i.e., t_{eff}) is the band descending/ascending gradient and t_channel (i.e., t_{channel}) is the thickness of the channel as described herein. This unitless parameter serves as a Figure of Merit to assess the performance of semiconductor heterostructure comprising the channel. FIG. 7A is an illustrative graph representing evolution of bandgap (eV) with electric field strength (eV/Angstrom) for As, Sb, Bi, Si, Ge, Sn, Pb with conventional stacking, and the bilayers separated by 3.5 Å, compared to bilayer graphene. FIG. 7B is an illustrative graph representing evolution of bandgap (eV) with electric field strength (eV/Angstrom) for As, Sb, Bi, Si, Ge, Sn, Pb with conventional stacking, and the bilayers separated by 8.5 Å, compared to bilayer graphene. FIG. 7C is an illustrative graph representing evolution of t_eff/t_channel versus band gap (eV) where the transparency of each scattered point represents the electric field strength (EF). Data shown correspond to As, Sb, Bi, Si, Ge, Sn, Pb with conventional stacking and the bilayers separated by 3.5 Å resulting in relaxed separation distance of 3.94, 4.12, 3.79, 2.53, 2.68, 3.00 and 3.14 Å for As, Sb, Bi, Si, Ge, Sn, Pb, respectively, as well as to bilayer graphene. FIG. 7D is an illustrative graph representing the evolution of t_eff/t_channel versus band gap (eV) where the transparency of each scattered point represents the electric field strength (EF). Data shown correspond to As, Sb, Bi, Si, Ge, Sn, Pb with conventional stacking and the bilayers separated by 8.5 Å, and to bilayer graphene. In some cases, 3.5 Å is a bilayer separation at the beginning of relaxation.

In FIGS. 7A-7D, the change of electronic structure upon application of an electric field for As, Sb, Bi, Si, Ge, Sn, Pb is illustrated for two different scenarios. In Scenario (I) the bilayers are separated by 3.5 Å at the start of the DFT relaxation calculations. Upon relaxation, this initial setup leads to interlayer distance of 3.94, 4.12, 3.79, 2.53, 2.68, 3.00 and 3.14 Å for As, Sb, Bi, Si, Ge, Sn, Pb, respectively. In Scenario (II) the bilayers are separated by 8.5 Å at the start of the DFT relaxation calculations. Upon relaxation, the initial interlayer distance is retained for all elements. In the legends of the graphs in FIGS. 7A-7D, the Scenario I and II data are labeled by using the initial distances “3.5” and “8.5” as suffixes.

Table 1 shows modeling results for bilayer structures containing atomically thin layers of Group IVA and Group VA materials separated by a 8.5 Å thick vacuum layer.

Table 1 shows that Pb, As, Sb and Bi all show much superior electric field response power compared to traditional materials such as bilayer graphene. A “band gap maximum” for heterostructure materials (i.e., the maximum bandgap of the bilayer structure over the electric field investigated) can be in a range from about 0.02 eV to about 2 eV, from about 0.1 eV to about 2 eV, from about 0.1 eV to about 1.5 eV, from about 0.4 eV to about 2 eV, or from about 0.4 eV to about 1.5 eV. An electric field needed to close the band gap (as described herein) for heterostructure materials can be in a range from about 0.05 eV/Å to about 0.5 eV/Å, from about 0.1 eV/Å to about 0.3 eV/Å. As used herein, “Max t_eff/t_channel” refers to the FOM described herein, and a value of maximum t_eff/t_channel (over the electric field range investigated for heterostructure materials), which can be in a range from about 0.2 to about 1, from about 0.3 to about 1, from about 0.4 to about 1, from about 0.5 to about 1, from about 0.55 to about 1, from about 0.6 to about 1, from about 0.7 to about 1, from about 0.8 to about 1, from about 0.9 to about 1, about 1, or less than about 1. In some cases, the FOM (t_eff/t_channel) can be greater than 1, from about 0.4 to about 1.1, from about 0.4 to about 1.2, less than about 1.1, or less than about 1.2.

To summarize the modelled results shown in Table 1, a band gap maximum for the IVA and VA bilayer structures investigated can be in a range from 0.027 eV for Si to 1.474 eV for As within the tested electric field (“EF”) range. An electric field needed to close the band gap for the IVA and VA bilayer structures investigated can be in a range from 0.04 eV/Å to 0.30 eV/Å. The Max t_eff/t_channel for the IVA and VA bilayer structures investigated can be in a range from 0.406 for Sn to 0.641 for As.

TABLE 1

| | Band gap | Electric field | |
|---|---|---|---|
| | maximum within | needed to | Max t_eff/ |
| Element/ | the tested | close the gap | t_channel |
| materials | EF range (eV) | (eV/Angstrom) | (absolute value) |
| Si | 0.027 | N/A | 0.439 |
| Ge | 0.024 | 0.04 | 0.459 |
| Sn | 0.071 | 0.04 | 0.406 |
| Pb | 0.396 | 0.09 | 0.551 |
| As | 1.474 | 0.30 | 0.641 |
| Sb | 0.995 | 0.30 | 0.619 |
| Bi | 0.478 | 0.10 | 0.540 |
| Bilayer | 0.298 | N/A | 0.196 |
| graphene | | | |

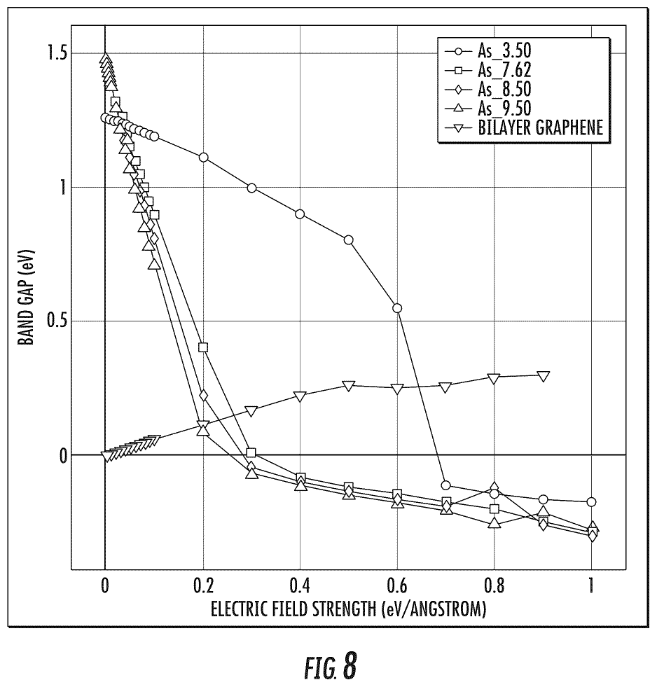

FIG. 8 is an illustrative graph showing evolution of band gaps (eV) versus electric field strength (eV/Angstrom) for bilayer arsenene (As) for different stacking distances 3.50 Å, 7.62 Å, 8.50 Å, 9.50 Å, compared to bilayer graphene. The interlayer distance can be a strong manipulating factor of the FOM (t_eff/t_channel). More particularly, the inventors determined that bilayer structures with larger separation distances (e.g., from about 7.6 Å to about 9.5 Å, from about 7 Å to about 10 Å, from about 1 nm to about 5 nm, or a few nanometers) can help enhance the electric field switch behavior.

However, larger separation distances in bilayer structures can raise mechanical stability concerns. In part, to address the stability concerns, the structures described herein can include a tunneling layer (also referred to as an atomically thin insulating layer herein) between the bilayer structure to stabilize the bilayer system, while retaining the rapid electric field switch effect.

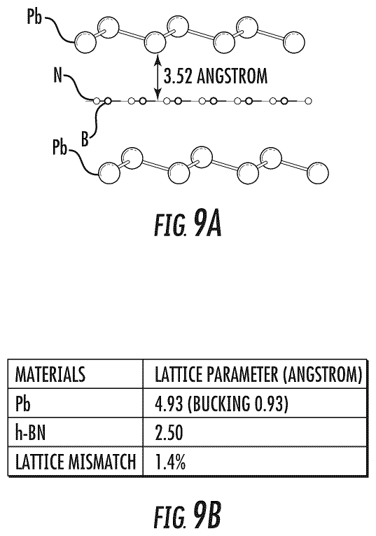

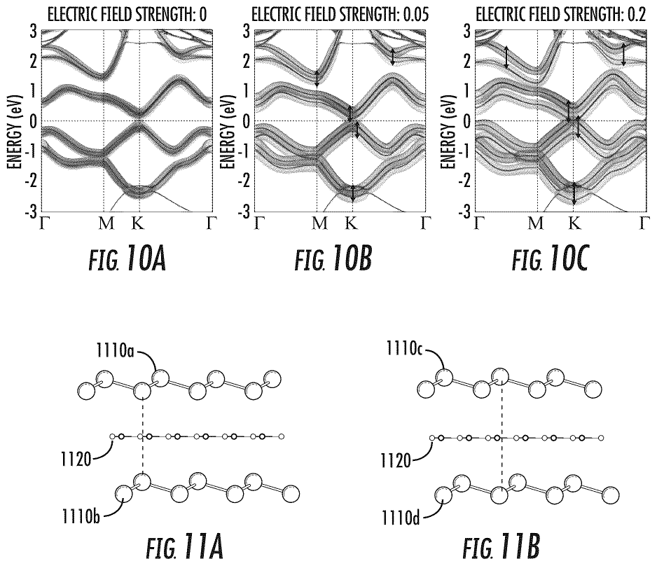

An example of a tunneling layer between the bilayer structure to stabilize the bilayer system is the bilayer plumbene (Pb) with hexagonal boron nitride (h-BN) tunneling layers. FIG. 9A is an illustrative drawing that shows bilayer plumbene (Pb) spaced apart by an h-BN layer. FIG. 9B is an illustrative chart that indicates lattice information for the structure of FIG. 9A. The chart indicates a lattice parameter for Pb of 4.93 Å (buckling 0.93 Å) and that shows a lattice parameter for h-BN of 2.50 Å, which indicates a lattice mismatch of 1.4%. In some cases, the layers of the bilayer heterostructures described herein can have large lattice mismatches, since the layers of the structure can be bonded together using van der Waals force and do not need to have crystal lattices that are epitaxially coherent with one another, which enables fabrication of atomically sharp heterointerfaces by thin-film deposition techniques such as chemical vapor deposition (CVD), molecular beam epitaxy (MBE), and atomic layer deposition (ALD). The materials described herein (e.g., plumbene), are particularly well suited for non-epitaxial growth techniques such as van der Waals epitaxy, as described herein. FIG. 10A is an illustrative drawing showing DFT results indicating electronic band structure for electric field strength 0 eV/Å for the bilayer plumbene (Pb) with a h-BN layer in between of FIG. 9A. FIG. 10B is an illustrative drawing showing DFT results indicating electronic band structure for electric field strength 0.05 eV/Å for the bilayer plumbene (Pb) with a h-BN layer in between of FIG. 9A. FIG. 10C is an illustrative drawing showing DFT results indicating electronic band structure for electric field strength 0.2 eV/Å for the bilayer plumbene (Pb) with a h-BN layer in between of FIG. 9A. The application of the electric field causes splitting of the bands of the bilayer structure, as shown by the bands in FIGS. 10B and 10C compared with the single bands shown in FIG. 10A.

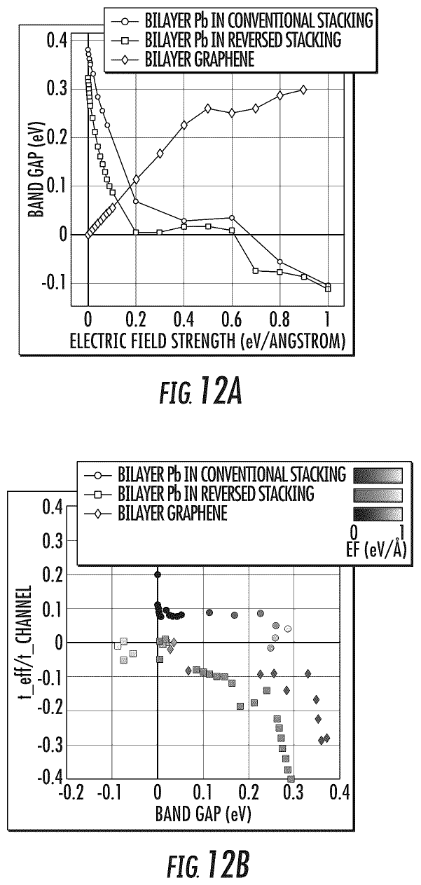

The tunneling layer creates a channel to enable interactions between two Pb monolayers. In some cases, the electric field switch effect is more significant when the two Pb layers are arranged in a reversed stacked manner. FIG. 11A is an illustrative drawing representing relaxed geometry conventional stacked bilayer plumbene (Pb) 1110a, 1110b stabilized by an h-BN tunneling layer 1120. FIG. 11B is an illustrative drawing representing relaxed geometry reversed stacked bilayer plumbene (Pb) 1120c, 1120d stabilized by an h-BN 1120 tunneling layer. FIG. 12A is an illustrative graph showing evolution of band gap (eV) versus electric field strength (eV/Angstrom) for both relaxed geometry conventional stacked, and relaxed geometry reversed stacked bilayer plumbene (Pb) stabilized by an h-BN tunneling layer, compared to bilayer graphene. FIG. 12B is an illustrative graph showing t_eff/t_channel versus band gap (eV) where the transparency of each scattered point represents the electric field strength (EF). Data shown correspond to the relaxed geometries of conventional stacked and reversed stacked bilayer plumbene (Pb) stabilized by an h-BN tunneling layer, and bilayer graphene for comparison. The graphs in FIGS. 12A-12B demonstrate that the reversed stacked bilayer plumbene (Pb) shows a greater change in bandgap with applied electric field (an improved FOM) compared to the conventional stacked bilayer.

In some cases, the structures described herein can use multiple h-BN layers in between two atomically thin semiconductor layers. Each layer of h-BN can be one monolayer of BN with a hexagonal arrangement of B and N atoms. The bilayer heterostructure materials combinations described herein can include insulating layers that are thin or atomically thin (e.g., up to 10 nm thick) and include multiple layers (e.g., multiple monolayers) of an insulating material (e.g., h-BN, sapphire (Al₂O₃), hafnia (HfO₂), etc.) and the electric field switch behavior still persists (e.g., as evidenced by an FOM greater than about 0.3, or from about 0.3 to about 1.0).

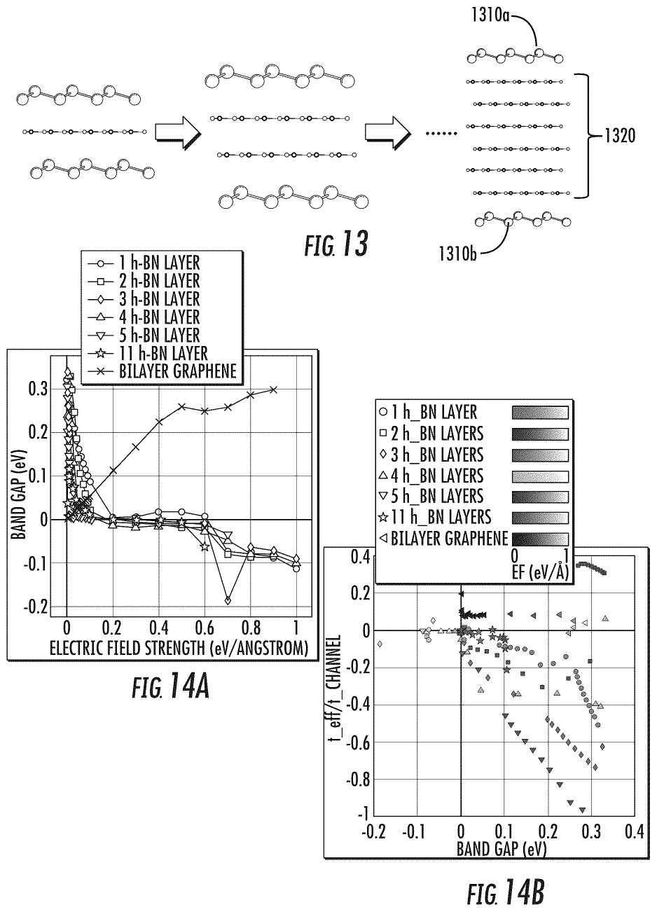

FIG. 13 is an illustrative schematic representing different numbers of h-BN layers 1320 between atomically thin semiconductor layers 1310a, 1310b. The left-most structure has one tunneling layer. The center structure has two tunneling layers. The right-most structure has six tunneling layers 1320. FIG. 14A is an illustrative graph showing the evolution of band gap (eV) versus electric field strength (eV/Angstroms) for 1, 2, 3, 4, 5, and 11 h-BN tunneling layers for a bilayer heterostructure including a bilayer of Pb and an h-BN insulating layer (i.e., a Pb-hBN-Pb system) compared to bilayer graphene. FIG. 14B is an illustrative graph showing the evolution of t_eff/t_channel versus band gap (eV) for 1, 2, 3, 4, 5, and 11 h-BN tunneling layers for an Pb-hBN-Pb system compared to bilayer graphene. Table 2 shows the electric field response power of the Pb-hBN-Pb system with respect to the number of h-BN layers and comparison with bilayer graphene.

TABLE 2

| | Band gap | Electric field | |
|---|---|---|---|
| Number | maximum within | needed to | Max t_eff/ |
| of h-BN | the tested EF | close the gap | t_channel |
| layers | range (eV) | (eV/Angstrom) | (absolute value) |
| 1 | 0.322 | 0.20 | 0.508 |
| 2 | 0.329 | 0.20 | 0.359 |
| 3 | 0.339 | 0.20 | 0.736 |
| 4 | 0.331 | 0.20 | 0.410 |
| 5 | 0.307 | 0.20 | 0.964 |
| 11 | 0.116 | 0.20 | 0.213 |
| Bilayer graphene | 0.298 | N/A | 0.196 |

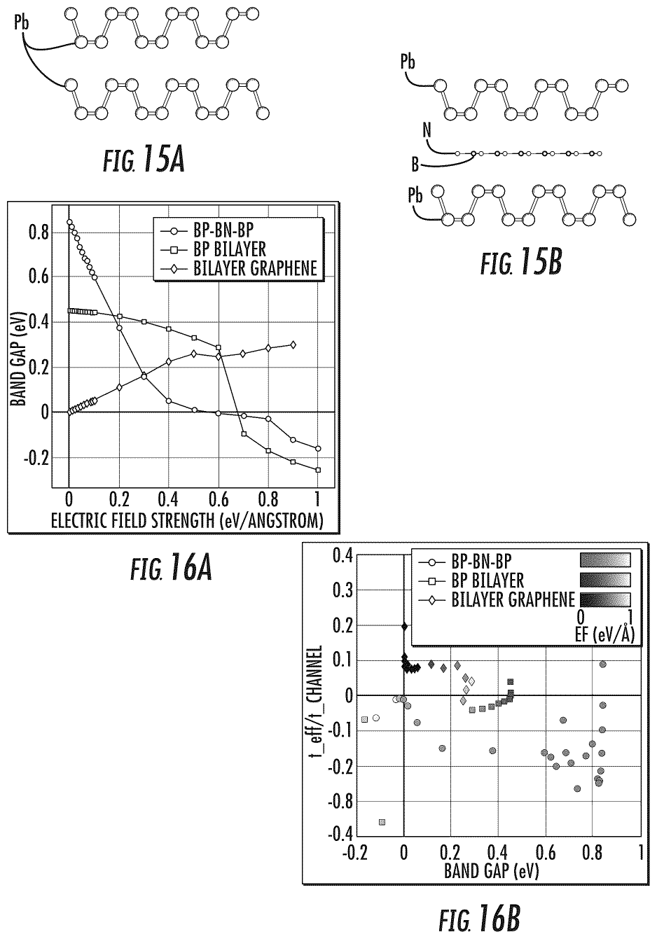

Another example demonstrating the benefit of the tunneling layer is a bilayer structure including black phosphorus. The tunneling layer has enabled the black phosphorus to exhibit a rapid electric field switch behavior compared to the free-floating bilayer structure. FIG. 15A is an illustrative drawing representing the geometry of bilayer black phosphorus. FIG. 15B is an illustrative drawing representing the geometry of bilayer black phosphorus (BP) with an h-BN interlayer (one monolayer of BN in this example) spacing apart the BP layers. FIG. 16A is an illustrative graph showing the evolution of band gap (eV) versus electric field strength (eV/Angstroms) for bilayer BP, bilayer BP with h-BN in between, and bilayer graphene. FIG. 16B is an illustrative graph showing the evolution of t_eff/t_channel versus band gap (eV) for bilayer BP, bilayer BP with h-BN in between, and bilayer graphene. FIGS. 16A-16B illustrate a rapid electric field switch in black phosphorus enabled by h-BN tunneling. Table 3 shows electric field response power of Bilayer BP with and without the h-BN tunneling layer and comparison with bilayer graphene.

TABLE 3

| | Band gap | Electric field | |
|---|---|---|---|
| | maximum within | needed to | Max t_eff/ |
| | the tested EF | close the gap | t_channel |
| Case | range (eV) | (eV/Angstrom) | (absolute value) |
| Bilayer BP | 0.450 | N/A | 0.041 |
| Bilayer BP with | 0.841 | 0.60 | 0.264 |
| h-BN | | | |
| Bilayer graphene | 0.298 | N/A | 0.196 |

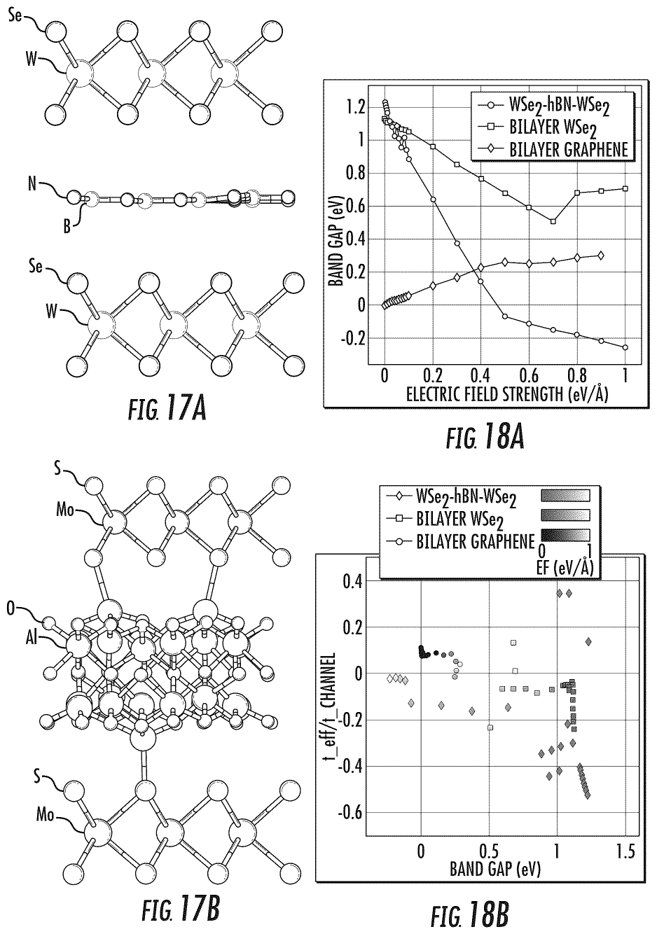

Another example demonstrating the benefit of the tunneling layer is a bilayer structure including a bilayer of WSe₂. In this case, which is similar to the bilayer black phosphorus case above, the h-BN tunneling or insulating layer has enabled the WSe₂ to exhibit a rapid electric field switch behavior compared to the free-floating bilayer WSe₂ structure, i.e. bilayer WSe₂ with no intervening tunneling layer. FIG. 17A is an illustrative drawing representing the geometry of bilayer WSe₂ with an h-BN tunneling or insulating layer between the WSe₂ layers. As in the cases above, the h-BN tunneling or insulating layer separates the WSe₂ layers, and spaces them apart from one another. FIG. 18A is an illustrative graph showing the evolution of band gap (eV) versus electric field strength (eV/Angstroms) for the bilayer WSe₂ with an h-BN layer separating the bilayer structure compared with conventional stacked bilayer WSe₂ (i.e. no intervening tunneling layer) and with bilayer graphene. FIG. 18B is an illustrative graph showing the evolution of t_eff/t_channel versus band gap (eV) for the bilayer WSe₂ with an h-BN layer separating the bilayer structure compared with conventional stacked bilayer WSe₂ and with bilayer graphene. FIGS. 18A-18B illustrate a rapid electric field switch in bilayer WSe₂ enabled by h-BN tunneling. These simulations show that the magnitude of the band gap changes for the bilayer WSe₂ with the h-BN layer are greater than those of the bilayer graphene, and the band gap changes are significant at relatively low applied electric fields. Additionally, the band gap of bilayer WSe₂ separated by an h-BN layer can be completely closed when the electric field reaches about 0.5 eV/Angstrom, while the gap closing effect cannot be seen in conventional stacked bilayer WSe₂ in the electric field range calculated.

Table 4 shows electric field response power of WSe₂ with and without the h-BN tunneling layer and a comparison with bilayer graphene.

TABLE 4

| | Band gap | Electric field | Max_t eff/ |
|---|---|---|---|
| | maximum within | needed to | t_channel |
| | the tested EF | close the gap | (absolute |
| Case | range (eV) | (eV/Angstrom) | value) |
| WSe₂-hBN-WSe₂ | 1.228 | 0.5 | 0.522 |
| Bilayer WSe₂ | 1.125 | N/A | 0.239 |
| MoS₂-Sapphire-MoS₂ | 0.415 | 0.3 | 0.606 |
| Bilayer MoS₂ | 1.197 | N/A | 0.253 |
| Bilayer graphene | 0.298 | N/A | 0.196 |

Another example demonstrating the benefit of the tunneling or insulating layer is a bilayer structure including a bilayer of MoS₂. This example is similar to the WSe₂ and the bilayer black phosphorus cases above, except that it includes an Al₂O₃ (sapphire) tunneling or insulating layer, which enabled the MoS₂ to exhibit a rapid electric field switch behavior, and a larger t_eff/t_channel compared to the free-floating bilayer structure. Table 4 also shows electric field response power of MoS₂ with and without the sapphire tunneling layer compared with bilayer graphene.

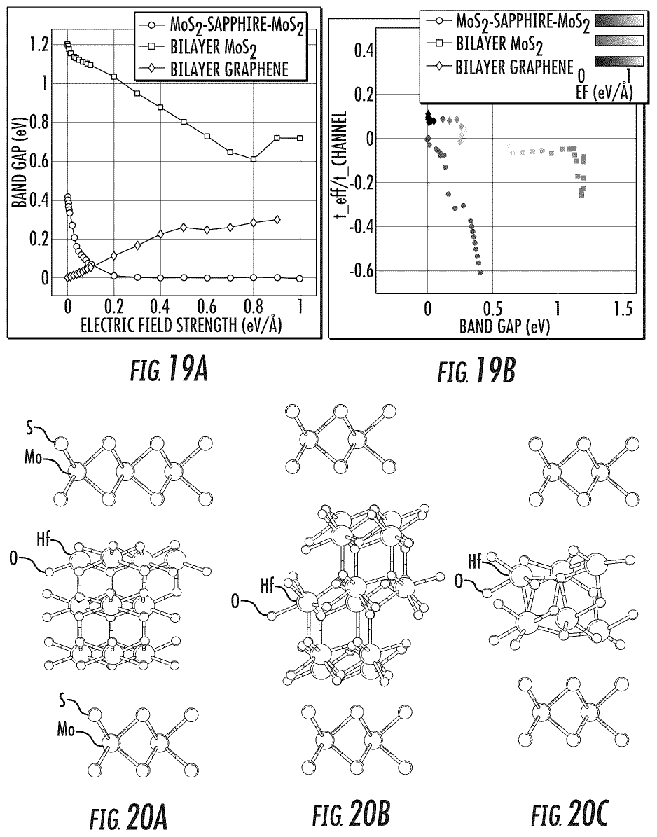

FIG. 17B is an illustrative drawing representing the geometry of bilayer MoS₂ with a sapphire tunneling or insulating interlayer spacing apart the MoS₂ layers. In this case, covalent bonds couple the MoS₂ layers and the sapphire tunneling or insulating layer to each other, as shown in the figure. FIG. 19A is an illustrative graph showing the evolution of band gap (eV) versus electric field strength (eV/Angstroms) for the bilayer MoS₂ with a sapphire layer separating the bilayer structure compared with conventional stacked bilayer MoS₂ (i.e., no intervening tunneling layer) and with bilayer graphene. FIG. 19B is an illustrative graph showing the evolution of t_eff/t_channel versus band gap (eV) for the bilayer MoS₂ with a sapphire layer separating the bilayer structure compared with conventional stacked bilayer MoS₂ and with bilayer graphene. FIGS. 19A-19B illustrate a rapid electric field switch in bilayer MoS₂ enabled by the sapphire tunneling layer. The band gap of bilayer MoS₂ separated by a sapphire layer is much smaller than that of conventional stacked bilayer MoS₂ due to the strong bonding between the MoS₂ and the sapphire. It is surprising that a large bandgap change (e.g., 0.4 eV) is predicted with relatively small applied electric fields (e.g., 0.2 eV/Angstrom) despite the strong bonding between the MoS₂ and the sapphire, but this finding indicates that the construction of bilayer heterostructures with high bandgap changes, and a large figure of merit, is not strictly limited to van der Waals interfaces between components, and can be achieved in covalently bonded heterostructures. The band gap of bilayer MoS₂ structure with the sapphire tunneling layer can be closed when the electric field reaches about 0.3 eV/Angstrom, while the gap closing effect cannot be seen in conventional stacked bilayer MoS₂ in the electric field range calculated.

Another example demonstrating the benefit of the tunneling or insulating layer is a bilayer structure including a bilayer of MoS₂ with a hafnia (HfO₂) tunneling or insulating layer between the layers of MoS₂. These structures are similar to the MoS₂ case above, except they include a hafnia tunneling or insulating layer. The hafnia (HfO₂) in the MoS₂ bilayer structures described herein can have different crystal phases, such as those with cubic crystal symmetry, hexagonal crystal symmetry, or a low degree of symmetry (e.g., no planes of symmetry).

For example, the structures can include a non-polar, polar, or low-symmetry hafnia tunneling or insulating layer. The non-polar hafnia described herein has a cubic crystal symmetry, and a space group P-43m (SG 215). The polar hafnia described herein has a trigonal crystal symmetry, and a space group R3m (SG 160). The low-symmetry hafnia described herein has a space group P1 (SG 1). The MoS₂ layers can each have a hexagonal crystal symmetry and a space group P63/mmc (SG 194), in some cases.

The hafnia tunneling or insulating layers described herein enable the MoS₂ bilayer structure to exhibit a rapid electric field switch behavior, and a large t_eff/t_channel. In some cases, the t_eff/t_channel of a structure with a MoS₂ bilayer and a hafnia tunneling or insulating layer is from about 0.3 to about 1.0, or from about 0.4 to about 1.0.

FIGS. 20A-20C show molecular structures of the geometry of MoS₂ bilayers with hafnia (HfO₂) tunneling or insulating layers. FIGS. 21A-23B show modelled electronic structure (bandgap and t_eff/t_channel) of bilayer MoS₂ with different types of hafnia (non-polar, polar, or low-symmetry) tunneling or insulating layers under electric field, in some cases, comparing the effect between electric field pointing from bottom-to-top and top-to-bottom. Table 5 summarizes the electric field response power of bilayer MoS₂ with and without the non-polar, polar, or low-symmetry hafnia tunneling or insulating layer, compared with the response of bilayer MoS₂ and with bilayer graphene structures.

TABLE 5

| | Band gap | | |
|---|---|---|---|
| | maximum | Electric field | Max t_eff/ |
| | within the | needed to | t_channel |
| | tested EF | close the gap | (absolute |
| Case | range (eV) | (eV/Angstrom) | value) |
| MoS₂-Non-polar hafnia- | 1.496 | N/A | 0.400 |
| MoS₂ | | | |
| MoS₂-Polar hafnia-MoS₂, | 1.408 | 0.5 | 0.417 |
| field from bottom to top | | | |
| MoS₂-Polar hafnia-MoS₂, | 1.408 | 0.5 | 1.005 |
| field from top-to-bottom | | | |
| MoS₂-Low-symmetry | 1.375 | N/A | 0.324 |
| hafnia-MoS₂, field from | | | |
| bottom to top | | | |
| MoS₂-Low-symmetry | 1.375 | N/A | 0.823 |
| hafnia-MoS₂, field from | | | |
| top-to-bottom | | | |
| Bilayer MoS₂ | 1.197 | N/A | 0.253 |
| Bilayer graphene | 0.298 | N/A | 0.196 |

FIG. 20A is an illustrative drawing that represents bilayer MoS₂ with a tunneling layer that is non-polar hafnia (HfO₂) between the layers of MoS₂. FIG. 20B is an illustrative drawing that represents bilayer MoS₂ with a tunneling layer that is polar hafnia (HfO₂) between the layers of MoS₂. FIG. 20C is an illustrative drawing that represents bilayer MoS₂ with a tunneling layer that is low-symmetry hafnia (HfO₂) between the layers of MoS₂.

The examples shown in FIGS. 20A-20C each include a bilayer MoS₂ with a hafnia layer separating the bilayer structure. In the case of the three different hafnia configurations (non-polar, polar, and low-symmetry), all configurations modelled showed excellent electric field switch behavior when compared with conventional stacked MoS₂ and bilayer graphene. A complete gap closing effect, however, was only seen for the structure including the polar hafnia tunneling or insulating layer.

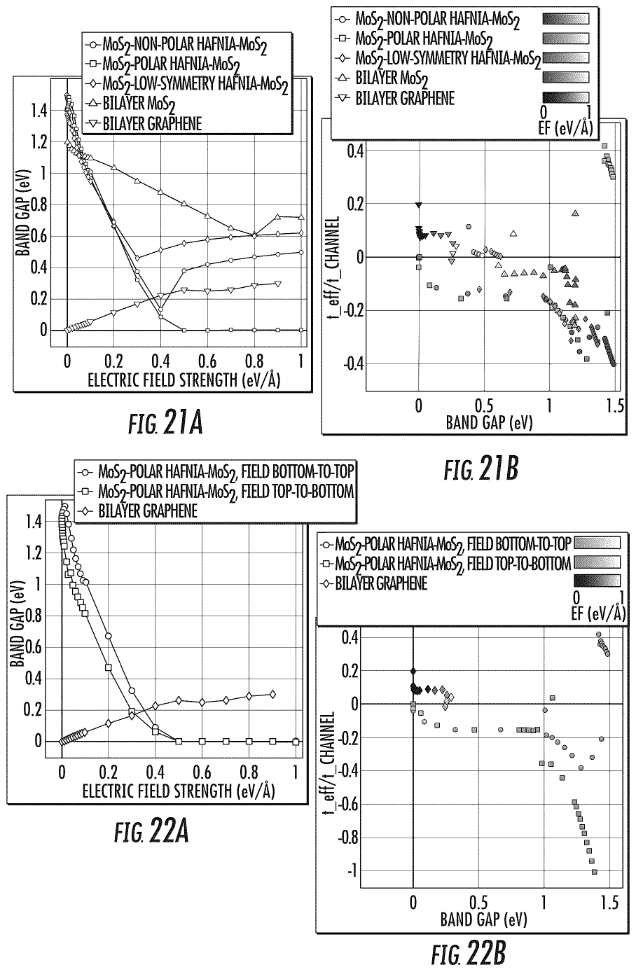

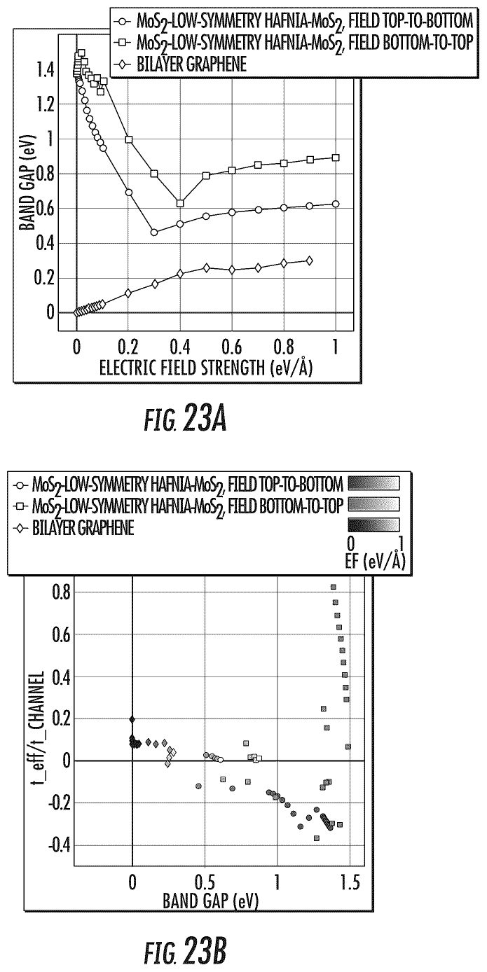

Because the polar and low-symmetry structures lack inversion symmetry, the effect of the electric field direction has also been calculated. The results (e.g., in FIGS. 22A-23B) show that the rapid electric-field switching behavior is maintained regardless of the field direction, although the t_eff/t_channel ratio exhibits a significant increase when the field direction is reversed.

FIG. 21A is an illustrative graph showing evolution of band gap (eV) versus electric field strength (eV/Å) for relaxed geometry of bilayer MoS₂ mechanically stabilized by a non-polar hafnia tunneling layer, a relaxed geometry of bilayer MoS₂ stabilized by a polar hafnia tunneling layer, and a relaxed geometry of bilayer MoS₂ stabilized by a low-symmetry hafnia tunneling layer, compared to conventional stacked MoS₂ and bilayer graphene. FIG. 21B is an illustrative graph showing t_eff/t_channel versus band gap (eV) for the relaxed geometry of bilayer MoS₂ stabilized by a non-polar hafnia tunneling layer, the relaxed geometry of bilayer MoS₂ stabilized by a polar hafnia tunneling layer, and the relaxed geometry of bilayer MoS₂ stabilized by a low-symmetry hafnia tunneling layer, compared to the conventional stacked MoS₂ and bilayer graphene. FIGS. 21A-21B illustrate a rapid electric field switch in bilayer MoS₂ with a non-polar, polar, or low-symmetry hafnia (HfO₂) tunneling or insulating layer. These simulations show that the magnitude of the band gap changes for the bilayer MoS₂ and hafnia structures are greater than those of the stacked MoS₂ and the bilayer graphene structures, and the band gap changes are significant at relatively low applied electric fields. Additionally, the band gap of the bilayer MoS₂ structure with the polar hafnia tunneling or insulating layer can be completely closed when the electric field reaches about 0.5 eV/Angstrom, while the gap closing effect was not seen in the other MoS₂/hafnia structures calculated in FIG. 21A.

FIG. 22A is an illustrative graph showing evolution of band gap (eV) versus electric field strength (eV/Å) for relaxed geometry of bilayer MoS₂ stabilized by a polar hafnia tunneling layer with electric field direction pointing from top to bottom and with electric field direction pointing from bottom to top, compared to that of bilayer graphene. FIG. 22B is an illustrative graph showing t_eff/t_channel versus band gap (eV) for the relaxed geometry of bilayer MoS₂ stabilized by a polar hafnia tunneling layer with electric field direction pointing from top to bottom and with electric field direction pointing from bottom to top, compared to that of bilayer graphene. The polar structure lacks inversion symmetry and is asymmetric in the direction of the electric field. The electric field direction from “bottom to top” is defined as along the [001] direction and the electric field direction from “top to bottom” is defined as along the [00-1] direction of the unit cell of the polar HfO₂ (with an R3m space group). In this case, the calculated effective bandgap was from about 0.0 eV to about 0.2 eV different, depending on the electric field direction and the magnitude of the applied bias, as illustrated by the curves shown in FIG. 22A. The t_eff/t_channel was significantly different depending on the electric field direction, where the maximum t_eff/t_channel was about 0.4 for the electric field pointing from bottom to top (in the [001] direction), and about 1.0 for the electric field pointing from top to bottom (in the [00-1] direction).

FIG. 23A is an illustrative graph showing evolution of band gap (eV) versus electric field strength (eV/Å) for relaxed geometry of bilayer MoS₂ stabilized by a low-symmetry hafnia tunneling layer with electric field direction pointing from top to bottom and with electric field direction pointing from bottom to top, compared to that of bilayer graphene. FIG. 23B is an illustrative graph showing t_eff/t_channel versus band gap (eV) for the relaxed geometry of bilayer MoS₂ stabilized by a low-symmetry hafnia tunneling layer with electric field direction pointing from top to bottom and with electric field direction pointing from bottom to top, compared to that of bilayer graphene. The low-symmetry structure lacks inversion symmetry and is asymmetric in the direction of the electric field. The electric field direction from “bottom to top” is defined as along the [001] direction and the electric field direction from “top to bottom” is defined as along the [00-1] direction of the unit cell of the low-symmetry HfO₂ (with P1 space group). In general, it is meaningless to specify a particular crystallographic direction for low-symmetry hafnia with a P1 space group. However, in this example, the low-symmetry hafnia structure was generated for the modelling by adding random displacements to the non-polar structure (space group P-43m), and that non-polar structure has defined crystallographic directions, so the electric field for the low-symmetry structure is defined along those [001] or [00-1] crystallographic directions. In this case, the calculated effective bandgap was from about 0.1 eV to about 0.3 eV different, depending on the electric field direction and the magnitude of the applied bias, as illustrated by the curves shown in FIG. 23A. The t_eff/t_channel was significantly different depending on the electric field direction, where the maximum t_eff/t_channel was about 0.3 for the electric field pointing from bottom to top (in the [001]direction), and about 0.8 for the electric field pointing from top to bottom (in the [00-1] direction).

The modelling results shown above for WSe₂ and MoS₂ bilayers including tunneling or insulating layers further demonstrate the generality of the concepts described herein, and show that structures with beneficial properties can be formed using bilayer structures including compound semiconductor layers with larger bandgaps (e.g., greater than 1 eV), and non-van der Waals insulating layers such as sapphire, with some degree of covalent bonding between semiconductor layers and the tunneling layer. The modelling results also show that an MoS₂ bilayer with a sapphire or hafnia tunneling or insulating layer can have beneficial properties, such as large bandgap changes upon application of relatively small electric fields. The modelling results additionally show that structures lacking inversion symmetry may lead to beneficial properties, for example, a higher magnitude of t_eff/t_channel for a particular electric field direction, and/or a bandgap which changes monotonically (for example, always increasing) as the electric field is changed from negative to positive direction over a range of electric fields near zero electric field.

The example structures and associated simulations described herein, including those shown in FIGS. 2D-23B, illustrate that bilayers including thin layers of materials separated by thin tunneling or insulating layers can be formed using several different types of materials. The materials, structures, and devices described herein can include: A) bilayers that are metallic, monometallic, pnictogens, or other elements (e.g., P, As, Sb, and Pb), sulfides (e.g., MoS₂), or selenides (e.g., MoSe₂), or transition metal dichalcogenide (TMD) films such as (Mo,W)(S,Se)₂; B) the bilayers can be separated using a thin tunneling or insulating layer such as a nitride (e.g., h-BN), or an oxide (e.g., sapphire or hafnia); and C) these different materials can be used to form bilayer structures that exhibit beneficial properties, such as large changes in bandgap (e.g., from about 0.2 eV to about 1.5 eV) between zero bias and at relatively small applied electric fields (e.g., less than 0.3 eV/Angstrom, or less than 0.5 eV/Angstrom), and high t_eff/t_channel ratios (FOMs) (e.g., from about 0.4 to about 1.0, from about 0.3 to about 1.0, or from about 0.3 to about 0.6). These bilayer structures can be used in semiconductor devices, such as transistors (e.g., NC-BCFETs).

### CLAUSES

Clause 1. A negative capacitance bandgap-change field-effect transistor (NC-BCFET) comprising: a channel comprising a bilayer heterostructure comprising: a first layer of a semiconductor material; a second layer of the semiconductor material; and an insulating layer between the first and second layers of the semiconductor material; wherein the first and second layers of the semiconductor material each comprise a thickness of 1 monolayer, or from 1 Å to 20 Å; a source in contact with a first region of the channel; a drain in contact with a second region the channel; a first ferroelectric layer in contact with a first side of the channel; a first gate layer in contact with the first ferroelectric layer, wherein the first ferroelectric layer is between the first gate layer and the channel; a second ferroelectric layer in contact with a second side of the channel opposite the first side; and a second gate layer in contact with the second ferroelectric layer, wherein the second ferroelectric layer is between the second gate layer and the channel; wherein the first and second regions are spaced apart from one another, and the first and second ferroelectric layers are in contact with the channel in a third region located between the first and second regions.

Clause 2. The NC-BCFET of clause 1, wherein the semiconductor material is selected from (Mo,W)(S,Se)₂, WSe₂, and MoS₂.

Clause 3. The NC-BCFET of clause 1, wherein the semiconductor material is selected from P, As, Sb, and Bi.

Clause 4. The NC-BCFET of clause 1, wherein the semiconductor material is selected from Si, Ge, Sn, and Pb.

Clause 5. The NC-BCFET of any of clauses 1-4, wherein a figure of merit teff/tchannel is in a range from about 0.4 to about 1.0.

Clause 6. The NC-BCFET of any of clauses 1-5, wherein the bilayer heterostructure of the channel comprises a band gap, wherein an electric field from about 0.04 eV/Angstrom to about 0.3 eV/Angstrom is able to close the band gap.

Clause 7. The NC-BCFET of any of clauses 1-6, wherein a band gap maximum for the bilayer heterostructure of the channel is in a range of 0.2 eV and 1.5 eV.

Clause 8. The NC-BCFET of any of clauses 1-7, wherein the insulating layer comprises hexagonal boron nitride (h-BN), non-polar hafnia, polar hafnia, low-symmetry hafnia, or sapphire.

Clause 9. The NC-BCFET of any of clauses 1-8, wherein the insulating layer comprises a thickness from 1 monolayer to 20 monolayers, or from 5 Å to 50 Å.

Clause 10. The NC-BCFET of any of clauses 1-9, wherein the channel comprises a hybridization energy less than 100 meV.

Clause 11. The NC-BCFET of any of clauses 1-10, wherein the insulating layer is a vacuum layer with a thickness from 5 Å to 100 Å.

Clause 12. The NC-BCFET of any of clauses 5-11, wherein the first and second layers of the semiconductor material each further comprise monoelemental monolayer honeycomb lattices.

Clause 13. The NC-BCFET of clause 1, wherein the first and second layers of the semiconductor material are monolayer lead (Pb) honeycomb lattice semiconductor layers separated by from 1 to 11 layers of hexagonal boron nitride (h-BN) insulator.

Clause 14. The NC-BCFET of clause 1, wherein the first and second layers of the semiconductor material are bilayer orthorhombic phosphorus (black phosphorus) semiconductor layers.

Clause 15. The NC-BCFET of clause 1, wherein: the semiconductor material is tungsten diselenide (WSe₂); and the insulating layer comprises hexagonal boron nitride.

Clause 16. The NC-BCFET of clause 1, wherein: the semiconductor material is molybdenum disulfide (MoS₂); and the insulating layer comprises sapphire that is covalently bonded to the first and second layers of the molybdenum disulfide semiconductor material.

Clause 17. The NC-BCFET of clause 1, wherein: the semiconductor material is molybdenum disulfide (MoS₂); and the insulating layer comprises non-polar hafnia, polar hafnia, or low-symmetry hafnia.

Clause 18. A negative capacitance bandgap-change field-effect transistor (NC-BCFET) comprising: a channel comprising: a first layer of a semiconductor material; a second layer of the semiconductor material; and an insulating layer between the first and second layers of the semiconductor material; wherein the semiconductor material is selected from P, As, Sb, Bi, Si, Ge, Sn, Pb, WSe₂, and MoS₂.

Clause 19. The NC-BCFET of clause 18, further comprising: a source in electrical contact with a first region of the channel; a drain in electrical contact with a second region the channel; and a first gate layer coupled to a third region of the channel; wherein the first and second regions are spaced apart from one another, and the third region of the channel is located between the first and second regions.

Clause 20. The NC-BCFET of clause 19 further comprising: a first ferroelectric layer in contact with a first side of the channel in the third region of the channel, wherein the first gate layer is in contact with the first ferroelectric layer, and the first ferroelectric layer is between the first gate layer and the channel; a second ferroelectric layer in contact with a second side of the channel opposite the first side in the third region of the channel; and a second gate layer in contact with the second ferroelectric layer, wherein the second ferroelectric layer is between the second gate layer and the channel.

Clause 21. A method of operating a negative capacitance bandgap-change field-effect transistor (NC-BCFET) comprising: a channel comprising a bilayer heterostructure comprising: a first layer of a semiconductor material; a second layer of the semiconductor material; and an insulating layer between the first and second layers of the semiconductor material; wherein the first and second layers of the semiconductor material each comprise a thickness of 1 monolayer, or from 1 Å to 20 Å; a source in contact with a first region of the channel; a drain in contact with a second region the channel; a first ferroelectric layer in contact with a first side of the channel; a first gate layer in contact with the first ferroelectric layer, wherein the first ferroelectric layer is between the first gate layer and the channel; a second ferroelectric layer in contact with a second side of the channel opposite the first side; and a second gate layer in contact with the second ferroelectric layer, wherein the second ferroelectric layer is between the second gate layer and the channel; wherein the first and second regions are spaced apart from one another, and the first and second ferroelectric layers are in contact with the channel in a third region located between the first and second regions, the method comprising: applying a first voltage to the first gate; applying a second voltage to the second gate; during an OFF-state, adjusting at least one of the first and second voltages, such that a first electric field magnitude across the channel causes a first band gap energy across the channel; and during an ON-state, adjusting at least one of the first and second voltages, such that a second electric field magnitude across the channel causes a second band gap energy across the channel; and wherein a difference between the first band gap energy during the OFF-state and the second band gap energy during the ON-state is at least 240 meV; and wherein a difference between the first electric field magnitude during the OFF-state and the second electric field magnitude during the ON-state is no more than 0.25 V/Angstrom.

Clause 22. The method of clause 21, wherein the band gap energy of the channel separates a lowest conduction band energy, primarily associated with one of the first and second semiconductor material layers, and a highest valence band energy, primarily associated with the other one of the first and second semiconductor material layers.

Clause 23. The method of clause 21, wherein, during the OFF-state, equal voltages are applied to the first and second gates; and wherein, during the ON-state, magnitude of the voltage applied to the second gate is larger than magnitude of the voltage applied to the first gate.

Clause 24. The method of clause 21, wherein, during the OFF-state, a difference between the first and second voltages is zero; and wherein, during the ON-state, magnitude of a difference between the first and second voltages is larger than zero volts.

Clause 25. The method of clause 21 further including: imparting a third voltage to the source; and imparting a fourth voltage to the drain; wherein, during OFF-state operation, a difference between the first, second, and third voltages is zero, and the fourth voltage is a positive voltage; and wherein during ON-state operation, a difference between the first and third voltages is zero, and the second and fourth voltages are positive voltages.

Clause 26. The method of clause 21 further including: imparting a third voltage to the source; imparting a fourth voltage to the drain; wherein, during OFF-state operation, a difference between the first, second, and third voltages is zero, and the fourth voltage is a negative voltage; wherein during ON-state operation, a difference between the first and third voltages is zero, and the second and fourth voltages are negative voltages.

Reference has been made in detail to examples of the disclosed invention, one or more examples of which have been illustrated in the accompanying figures. Each example has been provided by way of explanation of the present technology, not as a limitation of the present technology. In fact, while the specification has been described in detail with respect to specific examples of the invention, it will be appreciated that those skilled in the art, upon attaining an understanding of the foregoing, may readily conceive of alterations to, variations of, and equivalents to these examples. For instance, features illustrated or described as part of one example may be used with another example to yield a still further example. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only and is not intended to limit the invention.

What is claimed is:

1. A negative capacitance bandgap-change field-effect transistor (NC-BCFET) comprising:
a channel comprising a bilayer heterostructure comprising:
a first layer of a semiconductor material;
a second layer of the semiconductor material; and
an insulating layer between the first and second layers of the semiconductor material;
wherein the first and second layers of the semiconductor material each comprise a thickness of 1 monolayer, or from 1 Å to 20 Å;
a source in contact with a first region of the channel;
a drain in contact with a second region the channel;
a first ferroelectric layer in contact with a first side of the channel;
a first gate layer in contact with the first ferroelectric layer, wherein the first ferroelectric layer is between the first gate layer and the channel;
a second ferroelectric layer in contact with a second side of the channel opposite the first side; and
a second gate layer in contact with the second ferroelectric layer, wherein the second ferroelectric layer is between the second gate layer and the channel;
wherein the first and second regions are spaced apart from one another, and the first and second ferroelectric layers are in contact with the channel in a third region located between the first and second regions.

2. The NC-BCFET of claim 1, wherein the semiconductor material is selected from (Mo,W)(S,Se)₂, WSe₂, and MoS₂.

3. The NC-BCFET of claim 1, wherein the semiconductor material is selected from P, As, Sb, and Bi.

4. The NC-BCFET of claim 1, wherein the semiconductor material is selected from Si, Ge, Sn, and Pb.

5. The NC-BCFET of claim 1, wherein a figure of merit t_{eff}/t_{channel} is in a range from about 0.4 to about 1.0.

6. The NC-BCFET of claim 1, wherein the bilayer heterostructure of the channel comprises a band gap, wherein an electric field from about 0.04 eV/Angstrom to about 0.3 eV/Angstrom is able to close the band gap.

7. The NC-BCFET of claim 1, wherein a band gap maximum for the bilayer heterostructure of the channel is in a range of 0.2 eV and 1.5 eV.

8. The NC-BCFET of claim 1, wherein the insulating layer comprises hexagonal boron nitride (h-BN), non-polar hafnia, polar hafnia, low-symmetry hafnia, or sapphire.

9. The NC-BCFET of claim 1, wherein the insulating layer comprises a thickness from 1 monolayer to 20 monolayers, or from 5 Å to 50 Å.

10. The NC-BCFET of claim 1, wherein the channel comprises a hybridization energy less than 100 meV.

11. The NC-BCFET of claim 1, wherein the insulating layer is a vacuum layer with a thickness from 5 Å to 100 Å.

12. The NC-BCFET of claim, wherein the first and second layers of the semiconductor material each further comprise monoelemental monolayer honeycomb lattices.

13. The NC-BCFET of claim 1, wherein the first and second layers of the semiconductor material are monolayer lead (Pb) honeycomb lattice semiconductor layers separated by from 1 to 11 layers of hexagonal boron nitride (h-BN) insulator.

14. The NC-BCFET of claim 1, wherein the first and second layers of the semiconductor material are bilayer orthorhombic phosphorus (black phosphorus) semiconductor layers.

15. The NC-BCFET of claim 1, wherein:
the semiconductor material is tungsten diselenide (WSe₂); and
the insulating layer comprises hexagonal boron nitride.

16. The NC-BCFET of claim 1, wherein:
the semiconductor material is molybdenum disulfide (MoS₂); and
the insulating layer comprises sapphire that is covalently bonded to the first and second layers of the molybdenum disulfide semiconductor material.

17. The NC-BCFET of claim 1, wherein:
the semiconductor material is molybdenum disulfide (MoS₂); and
the insulating layer comprises non-polar hafnia, polar hafnia, or low-symmetry hafnia.

18. A negative capacitance bandgap-change field-effect transistor (NC-BCFET) comprising:
a channel comprising:
a first layer of a semiconductor material;
a second layer of the semiconductor material; and
an insulating layer between the first and second layers of the semiconductor material;
wherein the semiconductor material is selected from P, As, Sb, Bi, Si, Ge, Sn, Pb, WSe₂, and MoS₂.

19. The NC-BCFET of claim, further comprising:
a source in electrical contact with a first region of the channel;
a drain in electrical contact with a second region the channel; and
a first gate layer coupled to a third region of the channel;
wherein the first and second regions are spaced apart from one another, and the third region of the channel is located between the first and second regions.

20. The NC-BCFET of claim further comprising:
a first ferroelectric layer in contact with a first side of the channel in the third region of the channel, wherein the first gate layer is in contact with the first ferroelectric layer, and the first ferroelectric layer is between the first gate layer and the channel;
a second ferroelectric layer in contact with a second side of the channel opposite the first side in the third region of the channel; and
a second gate layer in contact with the second ferroelectric layer, wherein the second ferroelectric layer is between the second gate layer and the channel.
